(19) United States
(12) Patent Application Publication
(10) Pub. No.: US 2025/0364448 A1
(43) Pub. Date: Nov. 27, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Lin-Yu HUANG, Hsinchu (TW); Shih-Fan CHEN, Hsinchu City (TW); Sheng-Fu HSU, Hsinchu (TW)

(21) Appl. No.: 19/293,118

(22) Filed: Aug. 7, 2025

Related U.S. Application Data
(63) Continuation of application No. 18/442,538, filed on Feb. 15, 2024.
(60) Provisional application No. 63/600,867, filed on Nov. 20, 2023.

(51) Int. Cl. H01L 23/58; H01L 21/768; H01L 23/528

(52) U.S. Cl. CPC H01L 23/585; H01L 21/768; H01L 23/528

(57) ABSTRACT

A semiconductor device includes an integrated circuit and one or more guard rings around the integrated circuit in a top view of the semiconductor device. At least one guard ring of the one or more guard rings includes an active region in the substrate, a first plurality of elongated conductive structures extending in a first direction in the top view of the semiconductor device and arranged in a second direction in the top view of the semiconductor device, and a second plurality of elongated conductive structures extending in the second direction and arranged in the first direction. The combination of the first and second pluralities of elongated conductive structures forms a conductive grid above the active region, and provides increased coverage of the surface area of the active region relative to including only the first plurality of elongated conductive structures or only the second plurality of elongated conductive structures.

### RELATED APPLICATIONS

This application is a continuation of U.S. patent application Ser. No. 18/442,538, filed Feb. 15, 2024, which claims the benefit of U.S. Patent Application No. 63/600,867, filed Nov. 20, 2023, the contents of which are incorporated herein by reference in their entireties.

### BACKGROUND

Guard rings are semiconductor structures that are often included around an integrated circuit of a semiconductor device to provide electrical isolation, electrostatic discharge (ESD) protection, and/or structural integrity, among other examples. A guard ring, for example, may be included to absorb charge carriers (e.g., electrons and/or holes) that form in a substrate of the semiconductor device due to substrate injection. These charge carriers, if accumulated in the substrate, may otherwise result in formation of a low-impedance path between the integrated circuit and an adjacent integrated circuit through the substrate. Such a low-impedance path may otherwise result in electrical shorting between the integrated circuits, which is referred to as “latch-up.” Latch-up may lead to degraded operation of the semiconductor device and/or may cause damage to the semiconductor device, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2I are diagrams of example implementations of a semiconductor device described herein.

FIGS. 3A-3D are diagrams of an example implementation of forming a guard ring of a semiconductor device described herein.

FIGS. 4A-4F are diagrams of example implementations of a semiconductor device described herein.

FIGS. 5A-5E are diagrams of an example implementation of forming a guard ring of a semiconductor device described herein.

FIG. 6 is a diagram of an example implementation of a semiconductor device described herein.

FIG. 7 is a diagram of an example implementation of a semiconductor device described herein.

FIG. 8 is a diagram of an example implementation of a semiconductor device described herein.

FIG. 9 is a diagram of an example implementation of a semiconductor device described herein.

FIG. 10 is a diagram of an example implementation of a semiconductor device described herein.

FIG. 11 is a diagram of an example implementation of a semiconductor device described herein.

FIG. 12 is a diagram of example components of a device described herein.

FIG. 13 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a guard ring may conduct charge carriers through conductive structures above an active region of the guard ring. The charge carrier absorption performance in the guard ring may be based at least in part on the surface area of the active region covered by the conductive structures. If an insufficient surface area of the active region is covered by the conductive structures, the guard ring may not provide sufficient charge carrier absorption, which may increase the likelihood of latch-up in the semiconductor device. However, the size and/or density of the conductive structures may be limited due to the placement of the conductive structures within a footprint or boundary of an interconnect structure above the conductive structures. Thus, the size and/or density of the conductive structures cannot result in the conductive structures extending laterally outward from the footprint or boundary of the interconnect structure. Alternatively, the distance or spacing between adjacent integrated circuits in the semiconductor device may be increased in order to reduce the likelihood of latch-up, at the expense of reduced integrated circuit density and/or increased size of the semiconductor device.

In some implementations described herein, a semiconductor device includes an integrated circuit and one or more guard rings around the integrated circuit in a top view of the semiconductor device. At least one guard ring of the one or more guard rings includes an active region in the substrate, a first plurality of elongated conductive structures extending in a first direction in the top view of the semiconductor device and arranged in a second direction in the top view of the semiconductor device, and a second plurality of elongated conductive structures extending in the second direction and arranged in the first direction. The combination of the first and second pluralities of elongated conductive structures forms a conductive grid above the active region, and provides increased coverage of the surface area of the active region relative to including only the first plurality of elongated conductive structures or only the second plurality of elongated conductive structures. The combination of the first and second pluralities of elongated conductive structures enables the coverage of the surface area to be increased in both the first direction and the second direction within a footprint or boundary of an interconnect structure above the first and second pluralities of conductive structures. In this way, the first and second pluralities of conductive structures enable a high amount of charge carrier absorption to be achieved in the semiconductor device (which may reduce the likelihood of latch-up in the semiconductor device) while enabling a short distance or spacing between adjacent integrated circuits in the semiconductor device to be achieved.

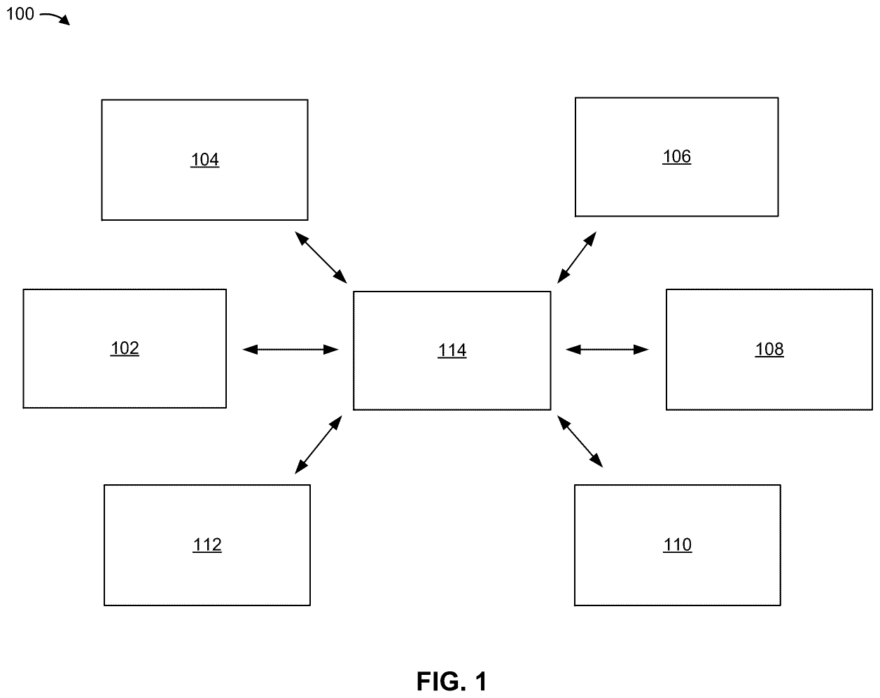

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, an ion implantation tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

In some implementations, a deposition tool 102 includes an electroplating tool and/or another type of plating tool that is capable of plating a substrate (e.g., a wafer, a semiconductor device, and/or the like) or a portion thereof with one or more metals. For example, a deposition tool 102 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The ion implantation tool 112 is a semiconductor processing tool that is used to implant ions into a substrate such as a semiconductor wafer. The ion implantation tool 112 generates ions in an arc chamber from a source material such as a gas or a solid. The source material is provided into the arc chamber, and an arc voltage is discharged between a cathode and an electrode to produce a plasma containing ions of the source material. One or more extraction electrodes are used to extract the ions from the plasma in the arc chamber and accelerate the ions to form an ion beam. The ion beam may be directed toward the substrate such that the ions are implanted below the surface of the substrate to dope the substrate.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 and/or the wafer/die transport tool 114 may be used to perform one or more semiconductor processing operations described herein. For example, one or more of the semiconductor processing tools 102-112 and/or the wafer/die transport tool 114 may be used to provide an active region around an integrated circuit device of a semiconductor device; form, above the active region, a first plurality of conductive structures extending in a first direction of the semiconductor device and arranged in a second direction in the semiconductor device that is approximately perpendicular with the first direction; form, above the active region, a second plurality of conductive structures extending in the second direction and arranged in the first direction, where the first plurality of conductive structures and the second plurality of conductive structures intersect to form a guard ring structure above the active region; and/or form one or more interconnect structures above the guard ring structure, among other examples.

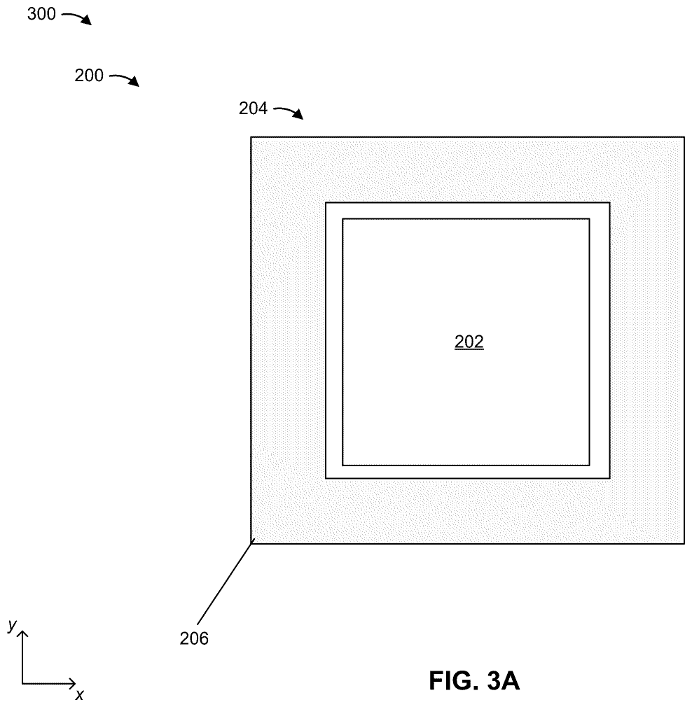

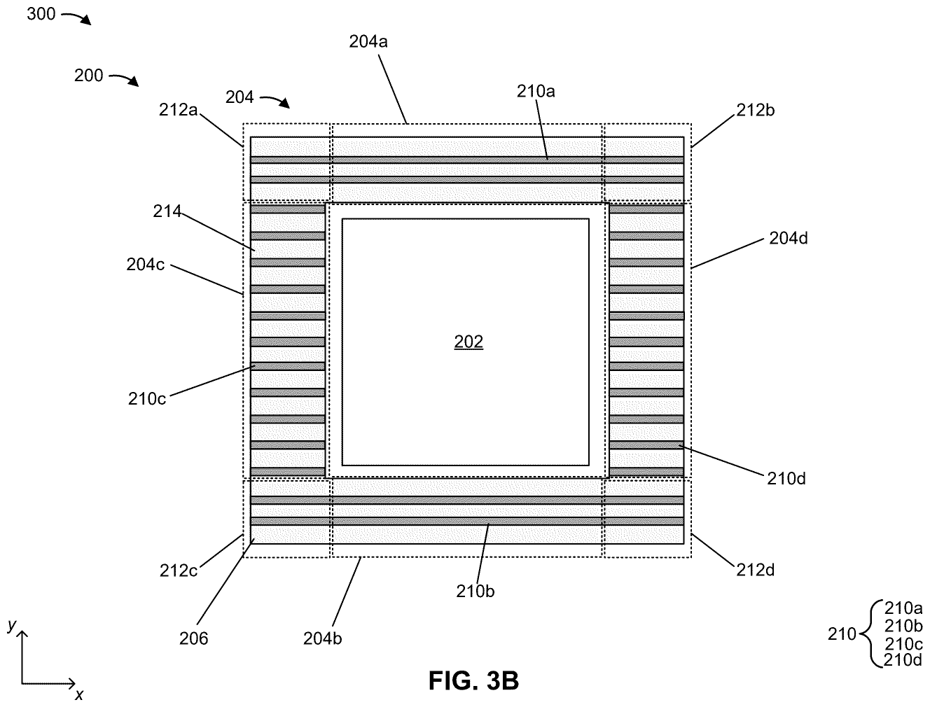

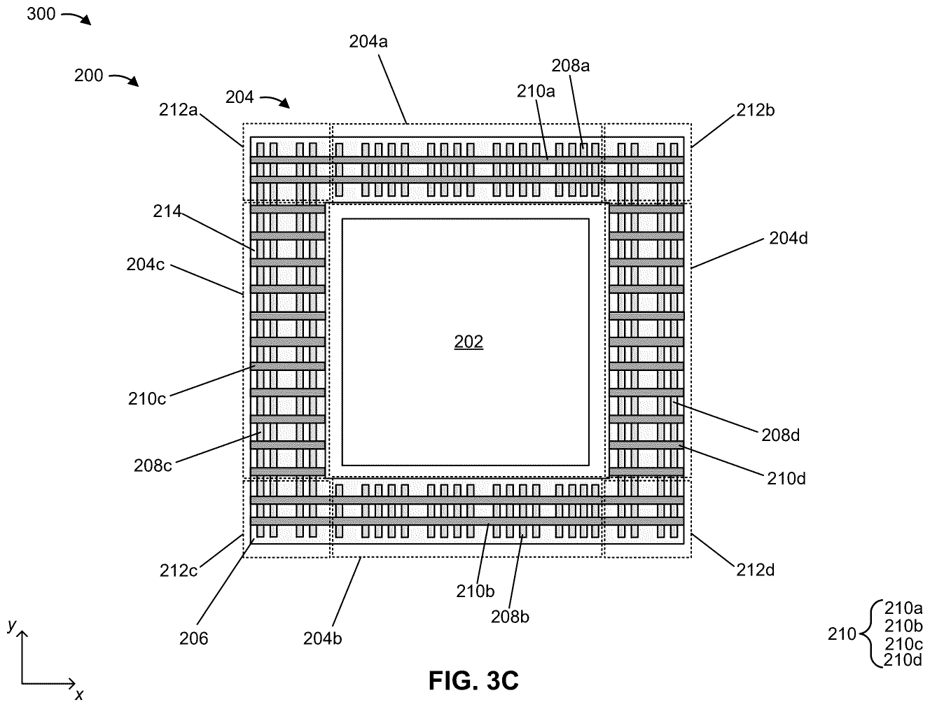

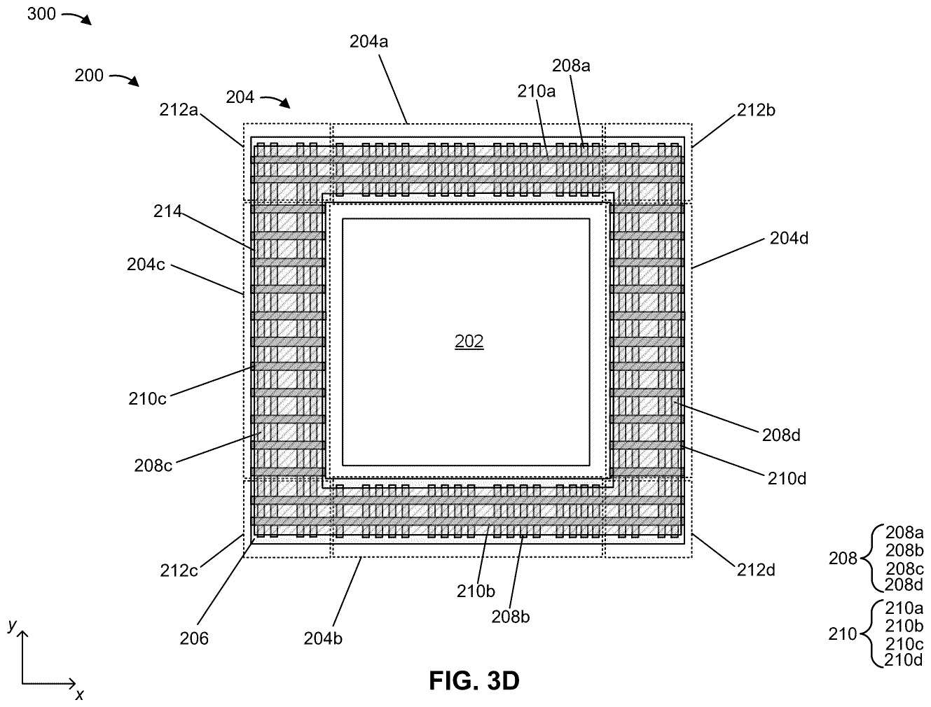

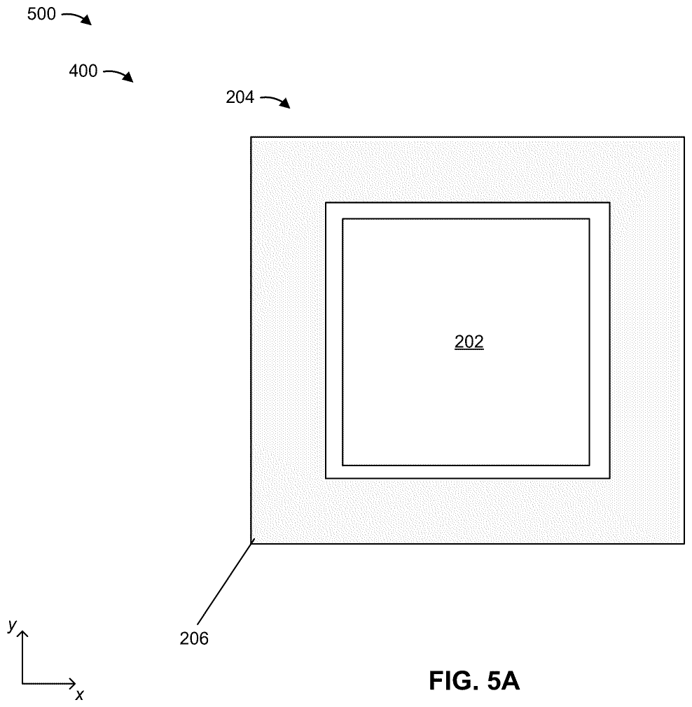

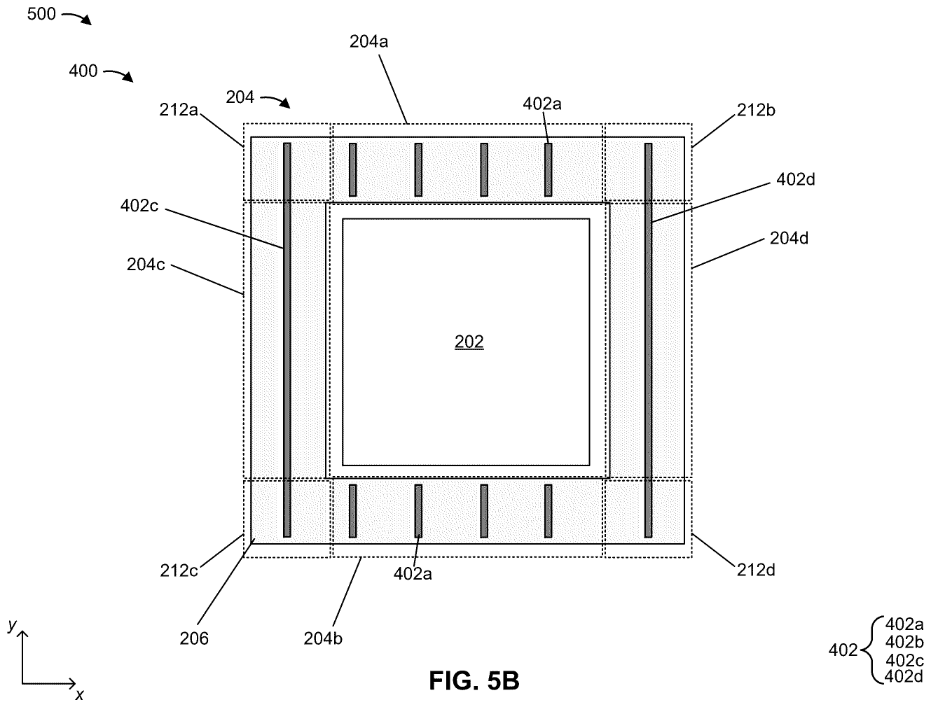

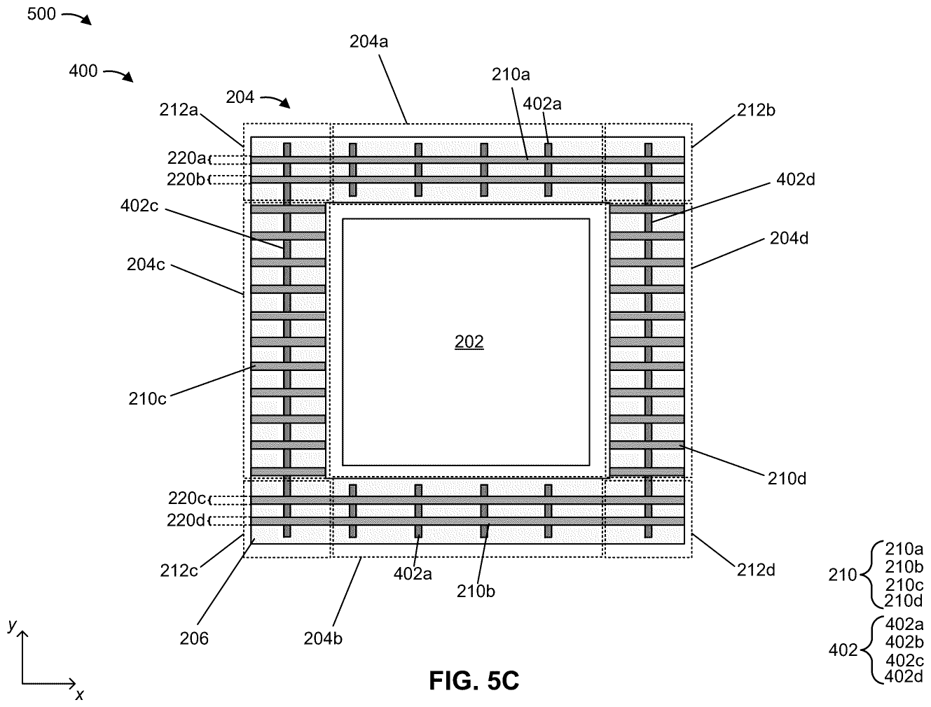

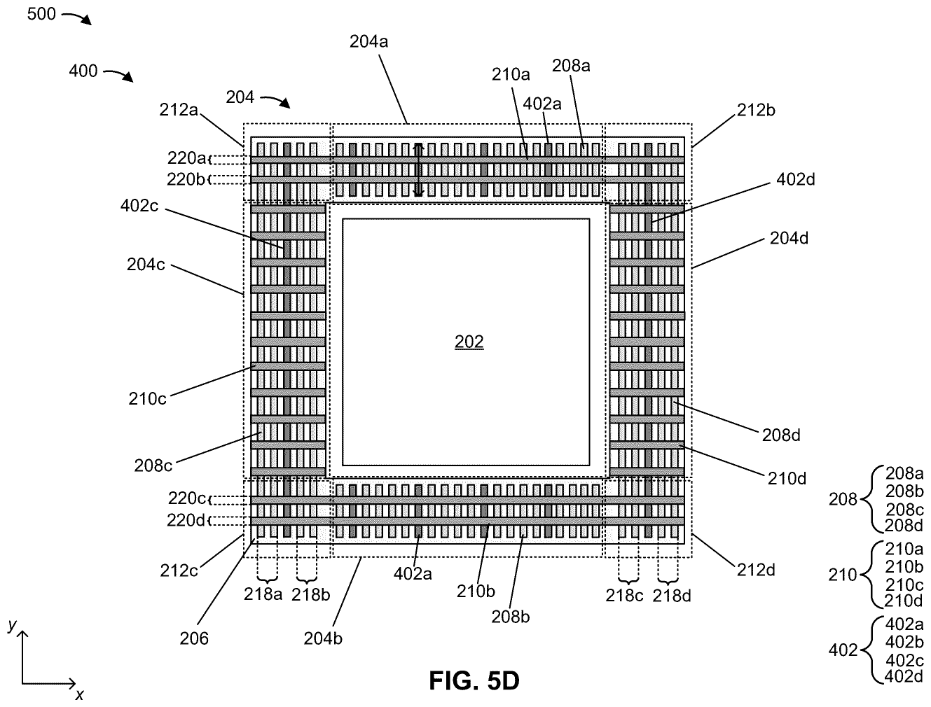

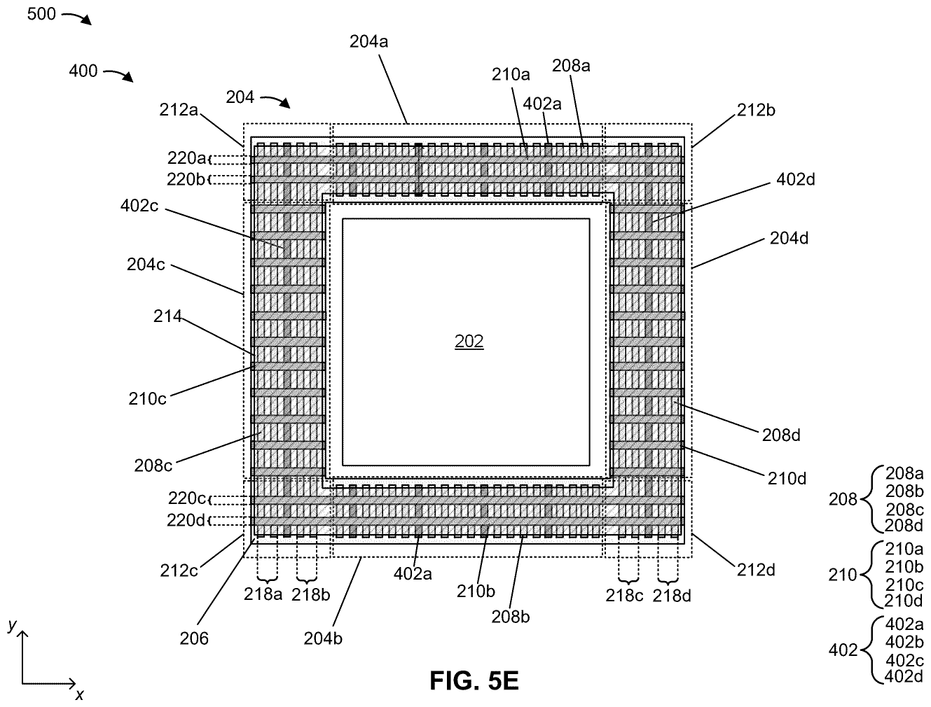

In some implementations, one or more of the semiconductor processing tools 102-112 and/or the wafer/die transport tool 114 may be used to perform one or more semiconductor processing operations described in connection with FIGS. 3A-3D, 5A-5E, and/or 13, among other examples.

The number and arrangement of devices shown in FIG. 1 is provided as an example. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

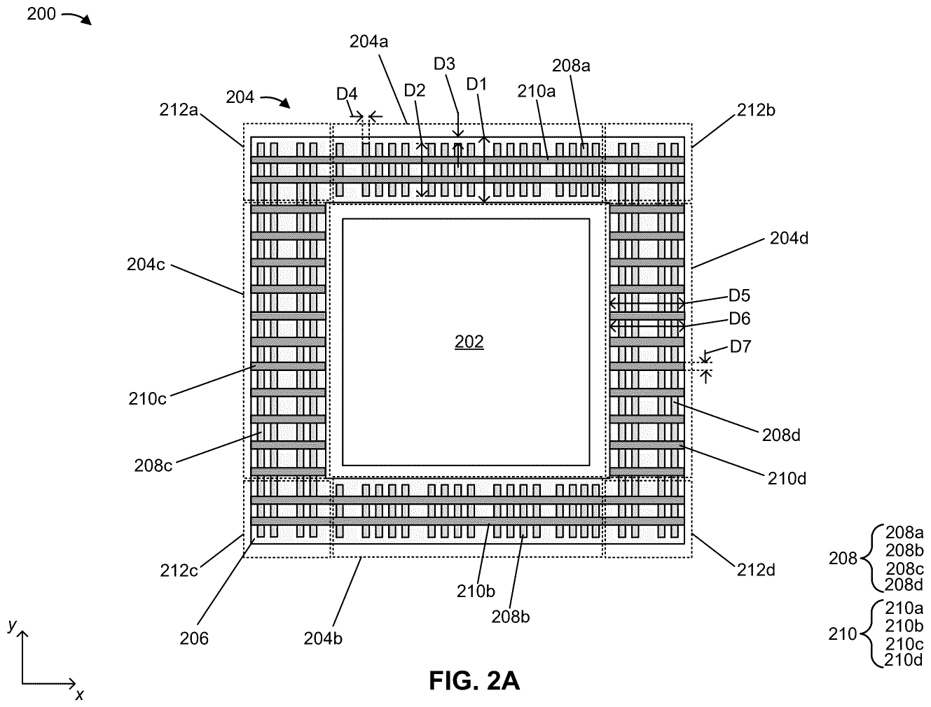

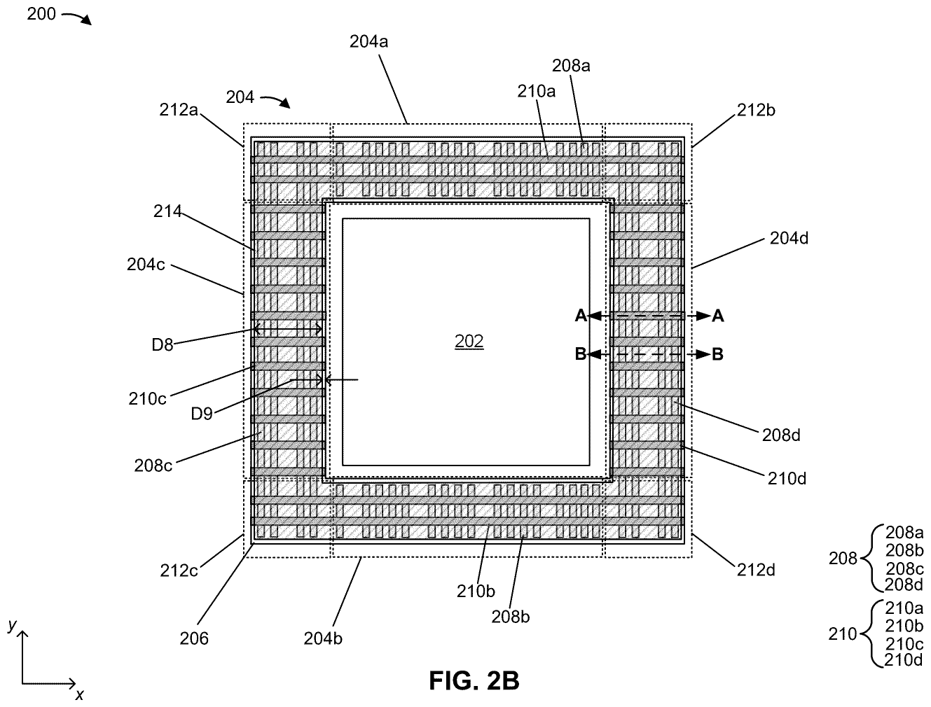

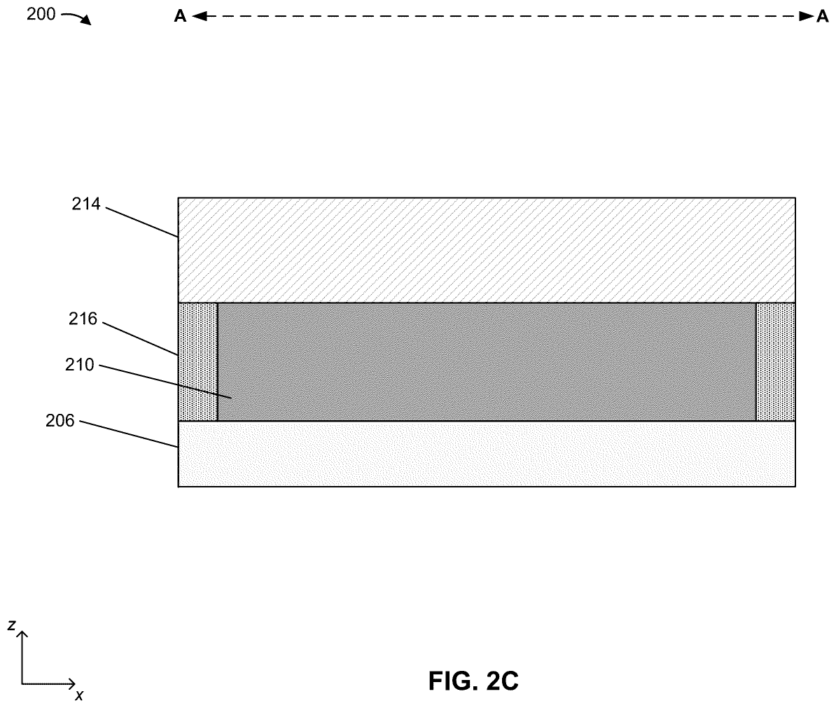

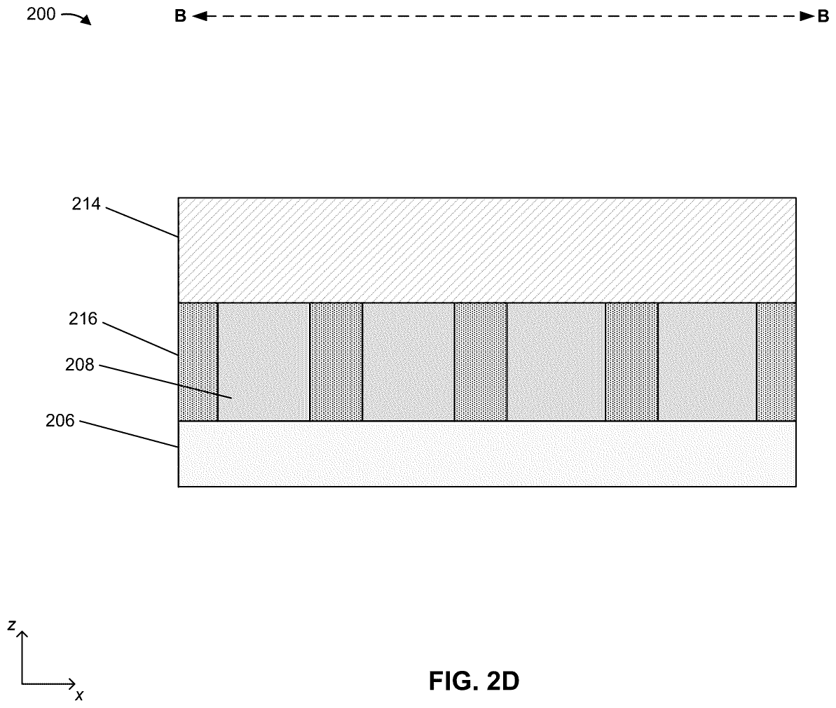

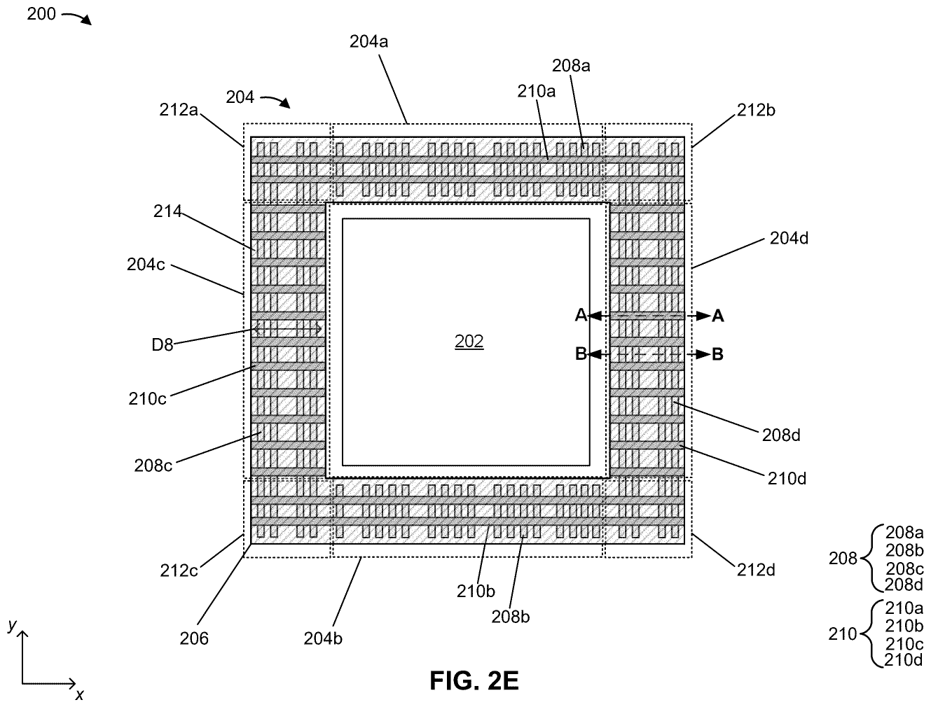

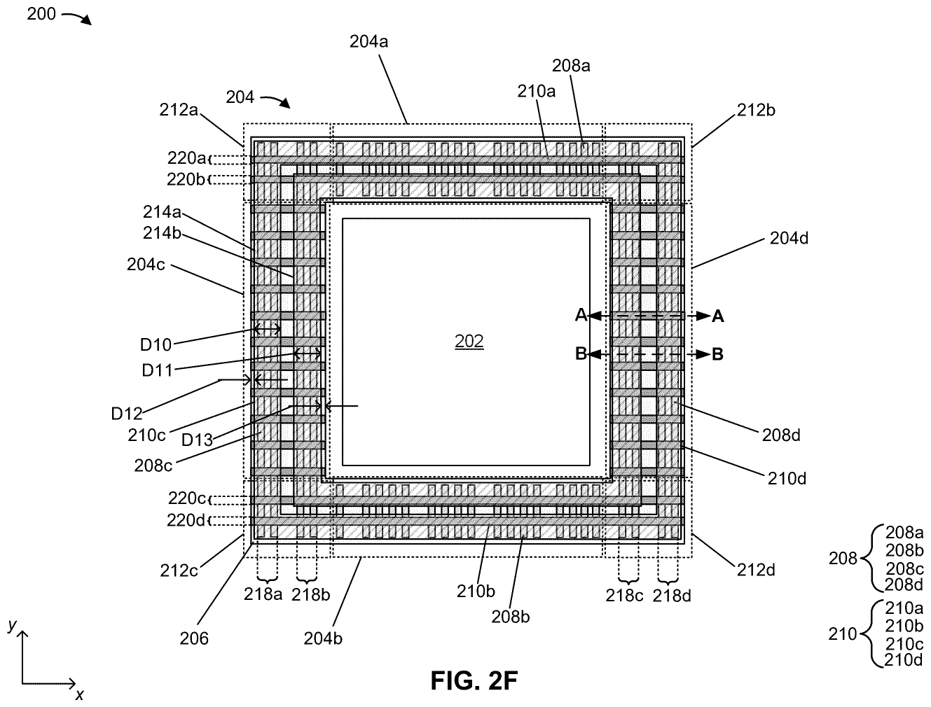

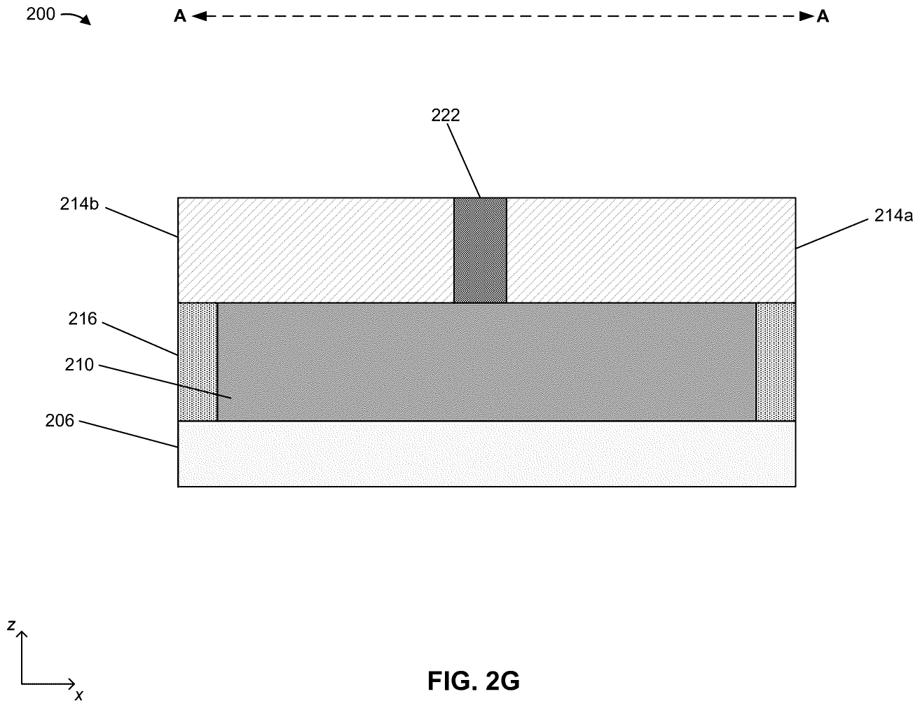

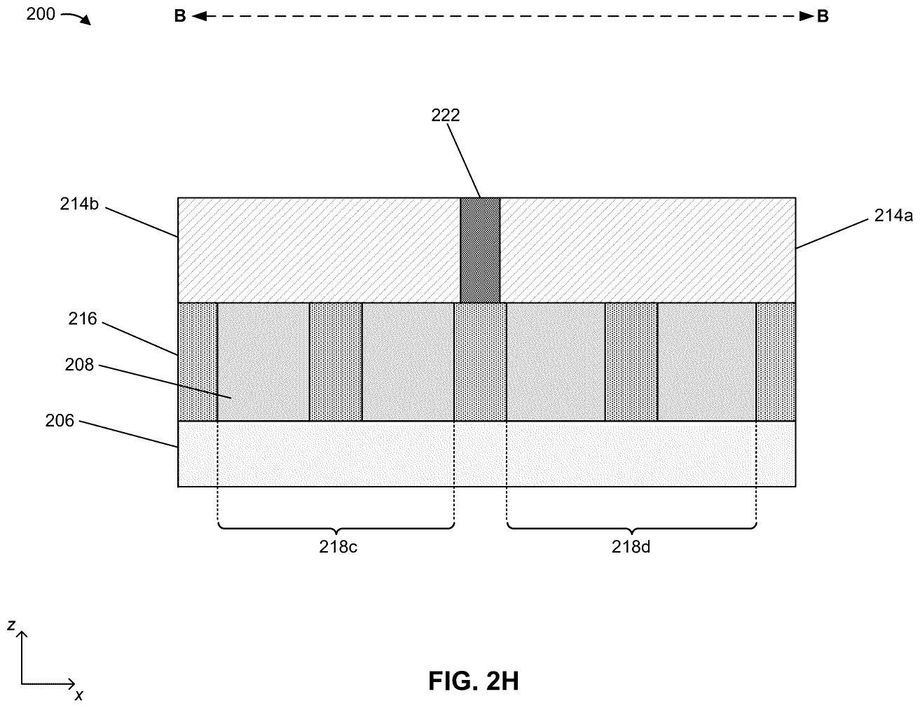

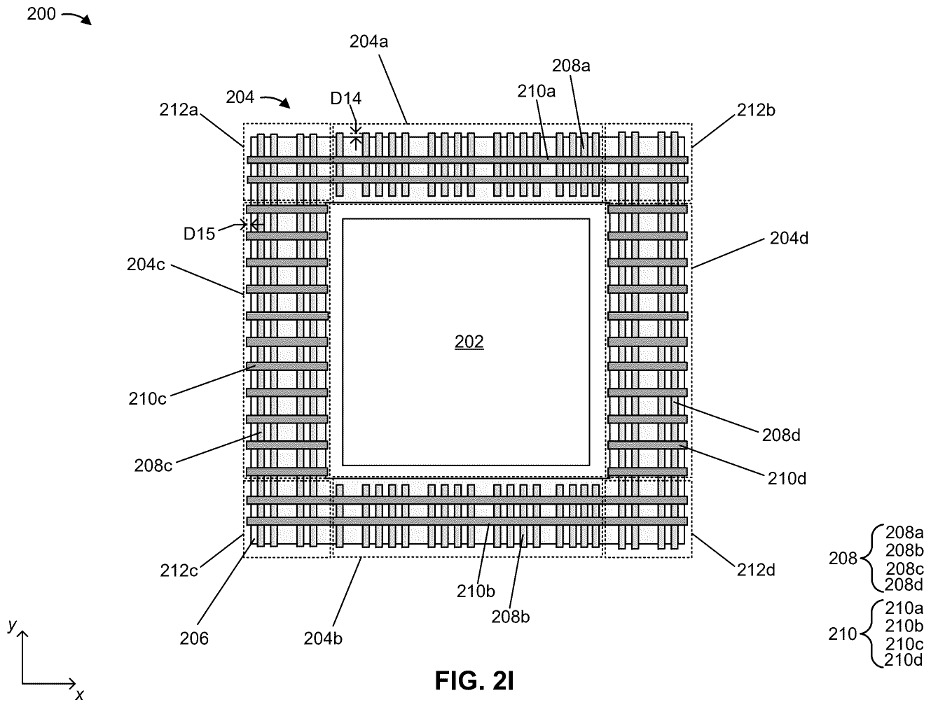

FIGS. 2A-2I are diagrams of example implementations of a semiconductor device 200 described herein. The semiconductor device 200 includes an example of a semiconductor device, such as a microprocessor (e.g., a central processing units (CPU)), a graphics processing units (GPU)), a memory device, an image sensor, and/or radio frequency (RF) device (e.g., an RF amplifier, an RF front-end device), among other examples.

FIGS. 2A and 2B illustrate top-down views of an example implementation of the semiconductor device 200. As shown in FIGS. 2A and 2B, the semiconductor device 200 includes an integrated circuit 202 and a guard ring structure 204 around the integrated circuit 202. The integrated circuit 202 may include one or more transistors, a memory cell array, and/or another type of integrated circuit 202. The transistor(s) may include planar transistor(s), fin-based transistor(s) (e.g., fin field effect transistor(s) (finFET(s)), nanostructure transistor(s) (e.g., nanowire transistor(s), nanosheet transistor(s), nanoribbon transistor(s), nanotube transistor(s), multi-bridge channel transistor(s), gate-all-around (GAA) transistor(s)), and/or another type of transistor(s). The size, shape, and/or orientation of the integrated circuit 202 illustrated in FIGS. 2A and 2B are examples, and other sizes, shapes, and/or orientations for the integrated circuit 202 are within the scope of the present disclosure.

The integrated circuit 202 may be formed in and/or above a substrate of the semiconductor device 200. The substrate may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

The guard ring structure 204 surrounds the integrated circuit 202 in the top view of the semiconductor device 200. The guard ring structure 204 is included around the integrated circuit 202 to provide electrical isolation, electrostatic discharge (ESD) protection, and/or structural integrity, for the integrated circuit 202 and/or other devices of the semiconductor device 200. The guard ring structure 204 includes an active region 206 around the integrated circuit 202 and a plurality of conductive structures 208 and 210 above the active region 206. The conductive structures 208 and 210 intersect to form a conductive grid of the guard ring structure 204 above the active region 206. The conductive structures 208 and 210 absorb charge carriers (e.g., electrons and/or holes) from the active region 206 that form in the substrate of the semiconductor device 200 due to substrate injection. In this way, the guard ring structure 204 prevents or reduces the likelihood of formation of low-impedance paths between the integrated circuit 202 and adjacent devices in the semiconductor device 200 through the substrate.

The active region 206 may include a portion of the substrate of the semiconductor device 200 around the integrated circuit 202. In some implementations, the active region 206 includes a doped portion of the substrate of the semiconductor device 200 around the integrated circuit 202 that is doped with one or more types of dopants (e.g., n-type dopants, p-type dopants). In some implementations, the active region 206 includes a ring of epitaxially grown semiconductor material (e.g., silicon (Si)) in the substrate around the integrated circuit 202. This active region 206 may continuously surround the integrated circuit 202, meaning that there are no discontinuities in the active region 206 around the integrated circuit 202. Alternatively, the active region 206 may include a plurality of discontinuous segments around the integrated circuit 202.

The conductive structures 208 are arranged in an x-direction in the top view of the semiconductor device 200 (e.g., are spaced apart in the x-direction) and extend in a y-direction in the top view of the semiconductor device 200. The conductive structures 208 may be included over and/or on the active region 206. The conductive structures 208 may be formed at the same time as source/drain contacts of the transistors in the integrated circuit 202. The conductive structures 208 may be formed of the same electrically conductive material(s) as the source/drain contacts, such as cobalt (Co), tungsten (W), ruthenium (Ru), titanium (Ti), copper, (Cu), and/or aluminum (Al), among other examples.

The conductive structures 208 may be arranged in the guard ring structure 204 in a plurality of sets of one or more conductive structures 208. For example, the guard ring structure 204 may include a plurality of segments, including a segment 204a, a segment 204b, a segment 204c, and a segment 204d, among other examples. The segment 204a may include one or more conductive structures 208a, the segment 204b may include one or more conductive structures 208b, the segment 204c may include one or more conductive structures 208c, and the segment 204d may include one or more conductive structures 208d.

The segments 204a and 204b may be on opposing sides of the integrated circuit 202 and may extend in the x-direction such that the segments 204a and 204b are approximately parallel. The segments 204c and 204d may be on opposing sides of the integrated circuit 202 and may extend in the y-direction such that the segments 204c and 204d are approximately parallel. Thus, the segments 204a and 204b are approximately perpendicular to the segments 204c and 204d. In some implementations, the segment 204c may include a quantity of conductive structures 208c that are included in a range from 1 to 8. However, other values for the range are within the scope of the present disclosure. In some implementations, the segment 204d may include a quantity of conductive structures 208d that are included in a range from 1 to 8. However, other values for the range are within the scope of the present disclosure.

The segments 204a and 204b may each have a y-direction width corresponding to a dimension D1 in FIG. 2A. In some implementations, the dimension D1 is included in a range of approximately 0.1 microns to approximately 5 microns. However, other values for the range are within the scope of the present disclosure.

In the example implementation illustrated in FIGS. 2A and 2B, a y-direction length of the conductive structures 208a and, in some implementations, a y-direction length of the conductive structures 208b (corresponding to dimension D2) may be less than the y-direction width of the segments 204a and 204b. Thus, the conductive structures 208a and/or 208b are fully contained within a top view footprint of the active region 206 in the example implementation illustrated in FIGS. 2A and 2B.

A distance between an end of a conductive structure 208a and an edge of the active region 206 in the segment 204a (corresponding to dimension D3), and/or a distance between an end of a conductive structure 208b and an edge of the active region 206 in the segment 204b, may be included in a range of approximately 0.01 microns to approximately 1 micron. However, other values for the range are within the scope of the present disclosure.

Additionally and/or alternatively, at least a subset of the conductive structures 208a and/or at least a subset of the conductive structures 208b may have a y-direction length that is approximately equal to the y-direction width of the active region 206 in the segments 204a and/or 204b (e.g., dimension D2 may be approximately equal to dimension D1).

An x-direction width of a conductive structure 208 (corresponding to dimension D4) may be included in a range of approximately 0.02 microns to approximately 1 micron. However, other values for the range are within the scope of the present disclosure.

The conductive structures 210 are arranged in the y-direction in the top view of the semiconductor device 200 (e.g., are spaced apart in the y-direction) and extend in the x-direction in the top view of the semiconductor device 200. The conductive structures 210 may be included over and/or on the active region 206. Thus, the conductive structures 210 are approximately perpendicular to the conductive structures 208. The conductive structures 210 may be formed at the same time as gate contacts of the transistors in the integrated circuit 202. The conductive structures 210 may be formed of the same electrically conductive material(s) as the source/drain contacts, such as cobalt (Co), tungsten (W), ruthenium (Ru), titanium (Ti), copper, (Cu), and/or aluminum (Al), among other examples.

The conductive structures 210 may be arranged in the guard ring structure 204 in a plurality of sets of one or more conductive structures 210. For example, the segment 204a may include one or more conductive structures 210a, the segment 204b may include one or more conductive structures 210b, the segment 204c may include one or more conductive structures 210c, and the segment 204d may include one or more conductive structures 210d. In some implementations, the segment 204a may include a quantity of conductive structures 210a that are included in a range from 1 to 8. However, other values for the range are within the scope of the present disclosure. In some implementations, the segment 204b may include a quantity of conductive structures 210b that are included in a range from 1 to 8. However, other values for the range are within the scope of the present disclosure.

The segments 204c and 204d may each have an x-direction width corresponding to a dimension D5 in FIG. 2A. In the example implementation illustrated in FIGS. 2A and 2B, an x-direction length of the conductive structures 210d and, in some implementations, an x-direction length of the conductive structures 210c (corresponding to dimension D6) may be approximately equal to the y-direction width of the segments 204c and 204d. Thus, the conductive structures 210c and/or 210d are fully contained within a top view footprint of the active region 206 in the example implementation illustrated in FIGS. 2A and 2B.

Additionally and/or alternatively, at least a subset of the conductive structures 210c and/or at least a subset of the conductive structures 210d may have an x-direction length that is less than the x-direction width of the active region 206 in the segments 204c and/or 204d (e.g., dimension D5 may be less than dimension D6). In these implementations, a distance between an end of a conductive structure 210d and an edge of the active region 206 in the segment 204d, and/or a distance between an end of a conductive structure 210c and an edge of the active region 206 in the segment 204c, may be included in a range of approximately 0.01 microns to approximately 1 micron. However, other values for the range are within the scope of the present disclosure.

A y-direction width of a conductive structure 210 (corresponding to dimension D7) may be included in a range of approximately 0.02 microns to approximately 1 micron. However, other values for the range are within the scope of the present disclosure.

The conductive structures 208a in the segment 204a intersect with conductive structures 210a in the segment 204a. The conductive structures 210a may be continuous along the x-direction in the segment 204a, and the conductive structures 208a may be discontinuous in the y-direction in that the continuity of the conductive structures 208a is interrupted by the conductive structures 210a. The conductive structures 208b in the segment 204b intersect with conductive structures 210b in the segment 204b. The conductive structures 210b may be continuous along the x-direction in the segment 204b, and the conductive structures 208b may be discontinuous in the y-direction in that the continuity of the conductive structures 208b is interrupted by the conductive structures 210b.

The conductive structures 208c in the segment 204c intersect with conductive structures 210c in the segment 204c. The conductive structures 210c may be continuous along the x-direction in the segment 204c, and the conductive structures 208c may be discontinuous in the y-direction in that the continuity of the conductive structures 208c is interrupted by the conductive structures 210c. The conductive structures 208d in the segment 204d intersect with conductive structures 210d in the segment 204d. The conductive structures 210d may be continuous along the x-direction in the segment 204d, and the conductive structures 208d may be discontinuous in the y-direction in that the continuity of the conductive structures 208d is interrupted by the conductive structures 210d.

The length of the conductive structures 208c and 208d respectively in the segments 204c and 204d is greater than the length of the conductive structures 208a and 208b respectively in the segments 204a and 204b. The length of the conductive structures 210a and 210b respectively in the segments 204a and 204b is greater than the length of the conductive structures 210c and 210d respectively in the segments 204c and 204d.

The segments 204a and 204c of the guard ring structure 204 are connected by a corner region 212a. The segments 204a and 204d of the guard ring structure 204 are connected by a corner region 212b. The segments 204b and 204c of the guard ring structure 204 are connected by a corner region 212c. The segments 204b and 204d of the guard ring structure 204 are connected by a corner region 212d.

The conductive structures 208c continuously extend through the segment 204c and intersect with one or more conductive structures 210a and 210b respectively in the corner regions 212a and 212c. The conductive structures 208d continuously extend through the segment 204d and intersect with one or more conductive structures 210a and 210b respectively in the corner regions 212b and 212d. The conductive structures 210a continuously extend through the segment 204a and intersect with one or more conductive structures 208c and 208d respectively in the corner regions 212a and 212b. The conductive structures 210b continuously extend through the segment 204b and intersect with one or more conductive structures 210c and 210d respectively in the corner regions 212c and 212d.

As shown in FIG. 2B, an interconnect structure 214 is included above the guard ring structure 204 around the integrated circuit 202. The interconnect structure 214 includes a metallization layer (e.g., an M1 metallization layer), or a portion thereof, of the semiconductor device 200. Charge carriers absorbed from the active region 206 in the guard ring structure 204 may be provided to the interconnect structure 214 through the conductive structures 208 and 210. The conductive grid formed by the conductive structures 208 and 210 provides increased charge carrier absorption relative to including only the conductive structures 208 or only the conductive structures 210 in the guard ring structure 204. The interconnect structure 214 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

A top view width (e.g., in the x-direction, in the y-direction) of the interconnect structure 214 (corresponding to dimension D8) may be less than the top view width of the active region 206 (e.g., the dimension D1, the dimension D5). In some implementations, the dimension D8 is included in a range of approximately 0.01 microns to approximately 4 microns. However, other values for the range are within the scope of the present disclosure. The interconnect structure 214 may be fully contained within the top view footprint of the active region 206. A distance between an edge of the interconnect structure 214 and an edge of the active region (corresponding to dimension D9) may be included in a range of approximately 0.01 microns to approximately 0.1 microns. However, other values for the range are within the scope of the present disclosure.

In the example implementation in FIG. 2B, the conductive structures 208 are fully contained within the top view footprint of the interconnect structure 214, and less than an entirety of the conductive structures 210 are contained within the top view footprint of the interconnect structure 214. In particular, ends of the conductive structures 210 extend laterally outward from the edges of the interconnect structure 214.

FIGS. 2C and 2D illustrate cross-sectional views of the example implementation of the semiconductor device 200 in FIGS. 2A and 2B. FIG. 2C illustrates a cross-sectional view along a line A-A in FIG. 2B. FIG. 2D illustrates a cross-sectional view along a line B-B in FIG. 2B.

As shown in FIG. 2C, the conductive structures 210 are located above and/or on the active region 206 in a z-direction in the semiconductor device 200, and the interconnect structure 214 is located above and/or on the conductive structures 210 in the z-direction. The conductive structures 210 may be physically isolated and/or electrically isolated from one another by dielectric regions 216. The dielectric regions 216 may include an interlayer dielectric (ILD) layer and/or another type of dielectric layer of the semiconductor device 200. The z-direction height of the conductive structures 210 and the z-direction height of the dielectric regions 216 may be approximately the same z-direction height such that the conductive structures 210 and the dielectric regions 216 are approximately co-planar.

The dielectric regions 216 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric regions 216 include an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

As shown in FIG. 2D, the conductive structures 208 are located above and/or on the active region 206 in the z-direction in the semiconductor device 200, and the interconnect structure 214 is located above and/or on the conductive structures 208 in the z-direction. The conductive structures 208 may be physically isolated and/or electrically isolated from one another by the dielectric regions 216. The z-direction height of the conductive structures 208 and the z-direction height of the dielectric regions 216 may be approximately the same z-direction height such that the conductive structures 208 and the dielectric regions 216 are approximately co-planar. Moreover, the z-direction height of the conductive structures 208 and the z-direction height of the conductive structures 210 may be approximately the same z-direction height such that the conductive structures 208 and the conductive structures 210 are approximately co-planar.

FIG. 2E illustrates a top-down view of another example implementation of the semiconductor device 200. The example implementation of the semiconductor device 200 illustrated in FIG. 2E is similar to the example implementation of the semiconductor device 200 illustrated in FIGS. 2A-2D, except that the edges of the interconnect structure 214 are substantially aligned with the edges of the active region 206. In other words, the top view width (dimension D8) of the interconnect structure 214, and the top view width (dimension D1, dimension D5) of the active region 206 are approximately equal. Thus, the conductive structures 208 and the conductive structures 210 are fully contained within the top view footprint of the interconnect structure 214 in the example implementation of the semiconductor device 200 illustrated in FIG. 2E.

FIG. 2F illustrates a top-down view of another example implementation of the semiconductor device 200. The example implementation of the semiconductor device 200 illustrated in FIG. 2F is similar to the example implementation of the semiconductor device 200 illustrated in FIGS. 2A-2D, except that a plurality of interconnect structures 214a and 214b are included above the guard ring structure 204. The interconnect structure 214a may be an outer interconnect structure that surrounds the interconnect structure 214b, which may be an inner interconnect structure. The interconnect structures 214a and 214b may be spaced apart such that the interconnect structures 214a and 214b are not in direct physical contact.

The interconnect structure 214a is located above a subset 218a of the conductive structures 208c in the segment 204c of the guard ring structure 204, and the interconnect structure 214b is located above another subset 218b of the conductive structures 208c in the segment 204c. The interconnect structures 214a and 214b extend in the y-direction across the conductive structures 210c in the segment 204c. In some implementations, the conductive structures 210c in the segment 204c extend in the x-direction laterally outward past the interconnect structures 214a and 214b such that portions of the conductive structures 210c are not under the interconnect structures 214a and 214b.

The interconnect structure 214a is located above a subset 218c of the conductive structures 208d in the segment 204d of the guard ring structure 204, and the interconnect structure 214b is located above another subset 218d of the conductive structures 208d in the segment 204d. The interconnect structures 214a and 214b extend in the y-direction across the conductive structures 210d in the segment 204d. In some implementations, the conductive structures 210d in the segment 204d extend in the x-direction laterally outward past the interconnect structures 214a and 214b such that portions of the conductive structures 210d are not under the interconnect structures 214a and 214b.

The interconnect structure 214a is located above a subset 220a of the conductive structures 210a in the segment 204a of the guard ring structure 204, and the interconnect structure 214b is located above another subset 220b of the conductive structures 208a in the segment 204a. The interconnect structures 214a and 214b extend in the x-direction across the conductive structures 208a in the segment 204a.

The interconnect structure 214a is located above a subset 220c of the conductive structures 210b in the segment 204b of the guard ring structure 204, and the interconnect structure 214b is located above another subset 220d of the conductive structures 210b in the segment 204b. The interconnect structures 214a and 214b extend in the y-direction across the conductive structures 210d in the segment 204d.

In the corner region 212a, the interconnect structure 214a is located over the subset 218a of the conductive structures 208c, over a portion of the subset 218b of the conductive structures 208c, over the subset 220a of the conductive structures 210a, and over a portion of the subset 220b of the conductive structures 210a. In the corner region 212a, the interconnect structure 214b is located over another portion of the subset 218b of the conductive structures 208c, and over another portion of the subset 220b of the conductive structures 210d.

In the corner region 212b, the interconnect structure 214a is located over the subset 218d of the conductive structures 208d, over a portion of the subset 218c of the conductive structures 208d, over the subset 220a of the conductive structures 210a, and over a portion of the subset 220b of the conductive structures 210a. In the corner region 212b, the interconnect structure 214b is located over another portion of the subset 218c of the conductive structures 208d, and over another portion of the subset 220b of the conductive structures 210d.

In the corner region 212c, the interconnect structure 214a is located over the subset 218a of the conductive structures 208c, over a portion of the subset 218b of the conductive structures 208c, over the subset 220d of the conductive structures 210b, and over a portion of the subset 220c of the conductive structures 210b. In the corner region 212b, the interconnect structure 214b is located over another portion of the subset 218b of the conductive structures 208c, and over another portion of the subset 220c of the conductive structures 210b.

In the corner region 212d, the interconnect structure 214a is located over the subset 218d of the conductive structures 208d, over a portion of the subset 218c of the conductive structures 208d, over the subset 220d of the conductive structures 210b, and over a portion of the subset 220c of the conductive structures 210b. In the corner region 212b, the interconnect structure 214b is located over another portion of the subset 218c of the conductive structures 208d, and over another portion of the subset 220c of the conductive structures 210b.

The interconnect structure 214a may have a top view width in the x-direction and/or in the y-direction (corresponding to dimension D10) that is included in a range of approximately 0.02 microns to approximately 1 micron. However, other values for the range are within the scope of the present disclosure. The interconnect structure 214a may have a top view width in the x-direction and/or in the y-direction (corresponding to dimension D11) that is included in a range of approximately 0.02 microns to approximately 1 micron. However, other values for the range are within the scope of the present disclosure. In some implementations, the dimension D10 and the dimension D11 are approximately equal values. In some implementations, the dimension D10 and the dimension D11 are different values.

In some implementations, a distance between an outer edge of the active region 206 and an outer edge of the interconnect structure 214a (corresponding to dimension D12) may be included in a range of approximately 0.01 microns to approximately 0.1 microns. However, other values for the range are within the scope of the present disclosure. In some implementations, a distance between an inner edge of the active region 206 and an inner edge of the interconnect structure 214b (corresponding to dimension D13) may be included in a range of approximately 0.01 microns to approximately 0.1 microns. However, other values for the range are within the scope of the present disclosure.

FIGS. 2G and 2H illustrate cross-sectional views of the example implementation of the semiconductor device 200 in FIG. 2F. FIG. 2G illustrates a cross-sectional view along the line A-A in FIG. 2F. FIG. 2H illustrates a cross-sectional view along a line B-B in FIG. 2F.

As shown in FIG. 2G, the interconnect structures 214a and 214b are located above and/or on at least a subset of the conductive structures 210 in the z-direction. As shown in FIG. 2H, the interconnect structures 214a and 214b are located above and/or on at least a subset (e.g., a subset 218c, a subset 218d) of the conductive structures 208 in the z-direction. The interconnect structures 214a and 214b may be physically isolated and/or electrically isolated from one another by dielectric regions 222. The dielectric regions 222 may include an ILD layer and/or another type of dielectric layer of the semiconductor device 200. The z-direction height of the interconnect structures 214a and 214b, and the z-direction height of the dielectric regions 222, may be approximately the same z-direction height such that the interconnect structures 214a and 214b, and the dielectric regions 222, are approximately co-planar.

The dielectric regions 222 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric regions 222 include an ELK dielectric material having a dielectric constant that is less than approximately 2.5.

FIG. 2I illustrates a top-down view of another example implementation of the semiconductor device 200. The example implementation of the semiconductor device 200 illustrated in FIG. 2I is similar to the example implementation of the semiconductor device 200 illustrated in FIGS. 2A-2D, except that one or more of the conductive structures 208 extend laterally outward past the edges of the active region 206, and/or one or more of the conductive structures 210 extend laterally outward past the edges of the active region 206. A conductive structure 208 may extend laterally outward past an edge of the active region 206 by a distance (corresponding to dimension D14) that is included in a range of approximately 0.01 microns to approximately 1 micron. However, other values for the range are within the scope of the present disclosure. A conductive structure 210 may extend laterally outward past an edge of the active region 206 by a distance (corresponding to dimension D15) that is included in a range of approximately 0.01 microns to approximately 1 micron. However, other values for the range are within the scope of the present disclosure.

As indicated above, FIGS. 2A-2I are provided as examples. Other examples may differ from what is described with regard to FIGS. 2A-2I.

FIGS. 3A-3D are diagrams of an example implementation 300 of forming a guard ring of a semiconductor device 200 described herein. The operations and/or techniques described in connection with the example implementation 300 may be performed to form one or more of the example implementations of the semiconductor device 200 illustrated and described in connection with FIGS. 2A-2D, 2E, 2F-2H, and/or 2I, among other examples. In some implementations, one or more of the semiconductor processing operations described in connection with FIGS. 3A-3D may be performed using one or more of the semiconductor processing tools 102-112 and/or the wafer/die transport tool 114. In some implementations, one or more of the semiconductor processing operations described in connection with FIGS. 3A-3D may be performed using another semiconductor processing tool.

As shown in FIG. 3A, the active region 206 of the guard ring structure 204 is provided around the integrated circuit 202 of the semiconductor device 200. In some implementations, the active region 206 is provided as a portion of a substrate of the semiconductor device 200. In some implementations, the active region 206 is formed by doping the substrate around the integrated circuit 202 with one or more types of dopants. For example, an ion implantation tool 112 may be used to implant dopants in the substrate around the integrated circuit 202 using an ion implantation technique and/or another type of technique to form the active region 206. In some implementations, a deposition tool 102 may be used to deposit the active region 206 using a PVD technique, an ALD technique, a CVD technique, an epitaxy technique, another type of deposition technique described in connection with FIG. 1, and/or another suitable deposition technique.

As shown in FIG. 3B, the conductive structures 210 are formed over and/or on the active region 206. The conductive structures 210 are formed such that the conductive structures 210 are arranged in the y-direction and extend in the x-direction in the semiconductor device 200.

A deposition tool 102 may be used to deposit the conductive structures 210 using a CVD technique, a PVD technique, an ALD technique, an electroplating technique, another deposition technique described above in connection with FIG. 1, and/or another suitable deposition technique. The conductive structures 210 may be deposited in one or more deposition operations. In some implementations, a seed layer is first deposited, and the conductive structures 210 are deposited on the seed layer. In some implementations, a planarization tool 110 may be used to planarize the conductive structures 210 after the conductive structures 210 are deposited.

In some implementations, a deposition tool 102 is used to form a dielectric layer, a deposition tool 102, an exposure tool 104, and a developer tool 106 are used to form a patterned masking layer on the dielectric layer, and an etch tool 108 is used to etch the dielectric layer based on the patterned masking layer to form the dielectric regions 216. The conductive structures 210 may then be formed in between the dielectric regions 216.

As shown in FIG. 3C, the conductive structures 208 are formed over and/or on the active region 206. The conductive structures 208 are formed such that the conductive structures 208 are arranged in the x-direction and extend in the y-direction in the semiconductor device 200. Moreover, the conductive structures 208 are formed such that the conductive structures 208 and the conductive structures 210 intersect to form a conductive grid above the active region 206.

A deposition tool 102 may be used to deposit the conductive structures 208 using a CVD technique, a PVD technique, an ALD technique, an electroplating technique, another deposition technique described above in connection with FIG. 1, and/or another suitable deposition technique. The conductive structures 208 may be deposited in one or more deposition operations. In some implementations, a seed layer is first deposited, and the conductive structures 208 are deposited on the seed layer. In some implementations, a planarization tool 110 may be used to planarize the conductive structures 208 after the conductive structures 208 are deposited.

In some implementations, a deposition tool 102 is used to form a dielectric layer, a deposition tool 102, an exposure tool 104, and a developer tool 106 are used to form a patterned masking layer on the dielectric layer, and an etch tool 108 is used to etch the dielectric layer based on the patterned masking layer to form the dielectric regions 216. The conductive structures 208 may then be formed in between the dielectric regions 216.

The order of operations illustrated and described in connection with FIGS. 3B and 3C are an example, and another order of operations may be used to form the conductive structures 208 and 210. For example, the conductive structures 208 may be formed first, and then the conductive structures 210 may be formed after the conductive structures 208.

As shown in FIG. 3D, an interconnect structure 214 is formed over and/or on the guard ring structure 204 such that the interconnect structure 214 is physically coupled and/or electrically coupled with the conductive structures 208 and the conductive structures 210. In some implementations, a plurality of interconnect structures 214a and 214b are formed over and/or on the guard ring structure 204 such that the interconnect structures 214a and 214b are spaced apart and are not in physical contact with one another.

A deposition tool 102 may be used to deposit the interconnect structure(s) 214 using a CVD technique, a PVD technique, an ALD technique, an electroplating technique, another deposition technique described above in connection with FIG. 1, and/or another suitable deposition technique. The interconnect structure(s) 214 may be deposited in one or more deposition operations. In some implementations, a seed layer is first deposited, and the interconnect structure(s) 214 are deposited on the seed layer. In some implementations, a planarization tool 110 may be used to planarize the interconnect structure(s) 214 after the interconnect structure(s) 214 are deposited.

In some implementations, a deposition tool 102 is used to form a dielectric layer, a deposition tool 102, an exposure tool 104, and a developer tool 106 are used to form a patterned masking layer on the dielectric layer, and an etch tool 108 is used to etch the dielectric layer based on the patterned masking layer to form the dielectric regions 222. The interconnect structure(s) 214 may then be formed in between the dielectric regions 222.

As indicated above, FIGS. 3A-3D are provided as an example. Other examples may differ from what is described with regard to FIGS. 3A-3D.

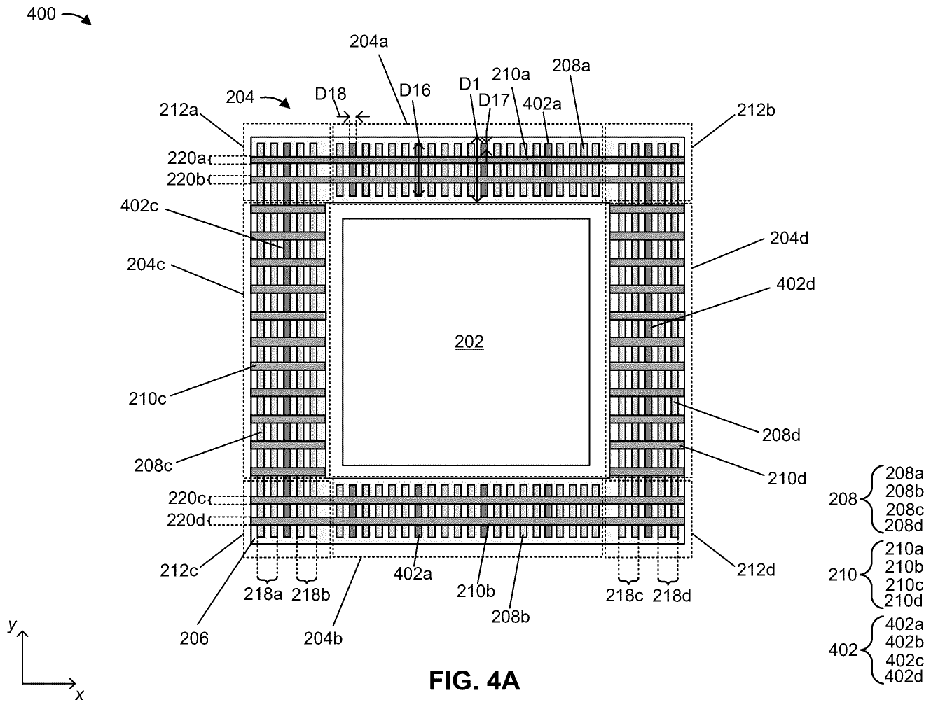

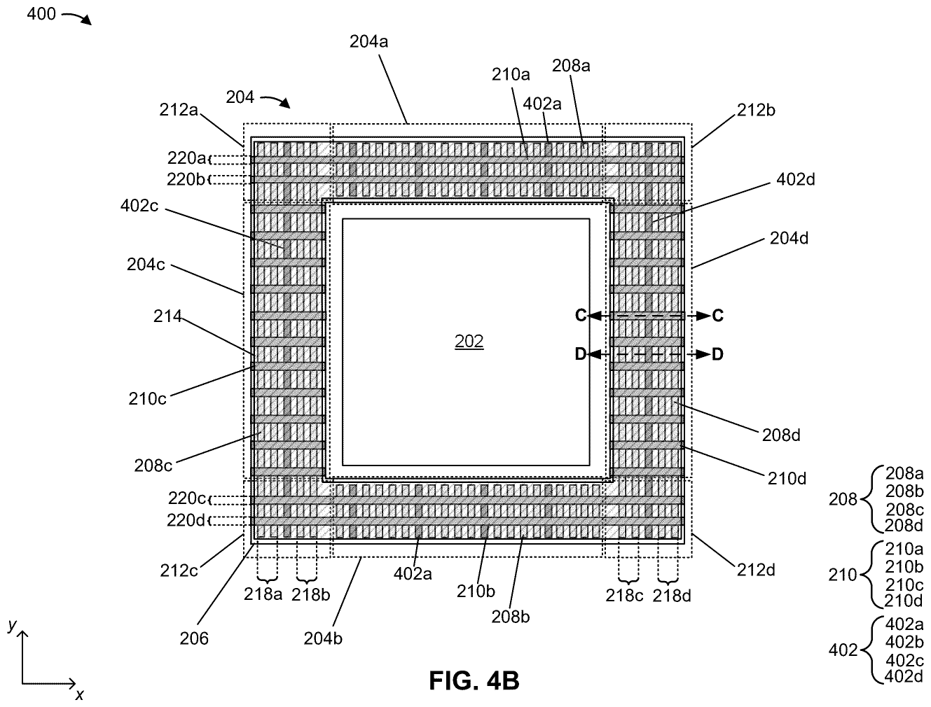

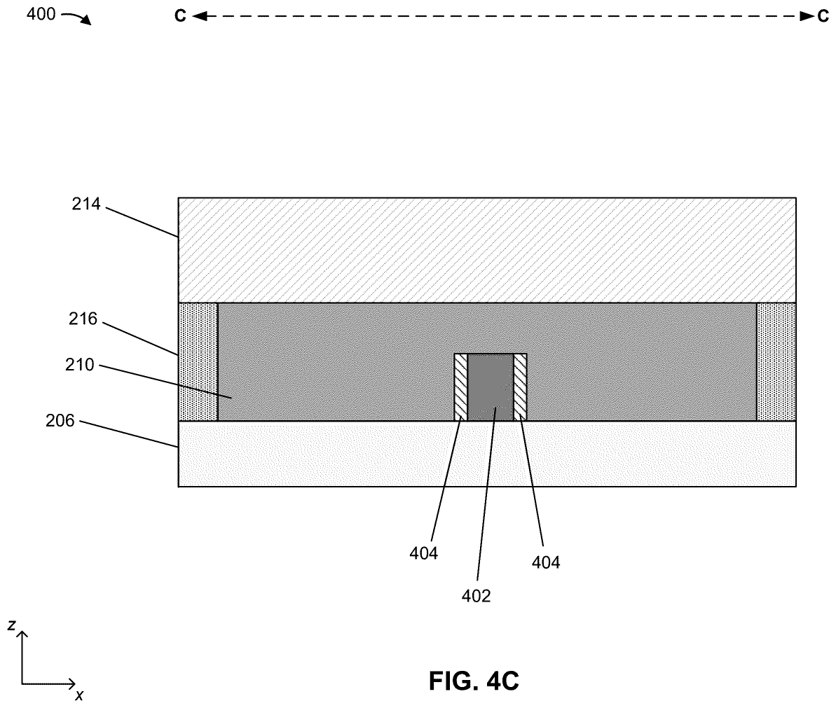

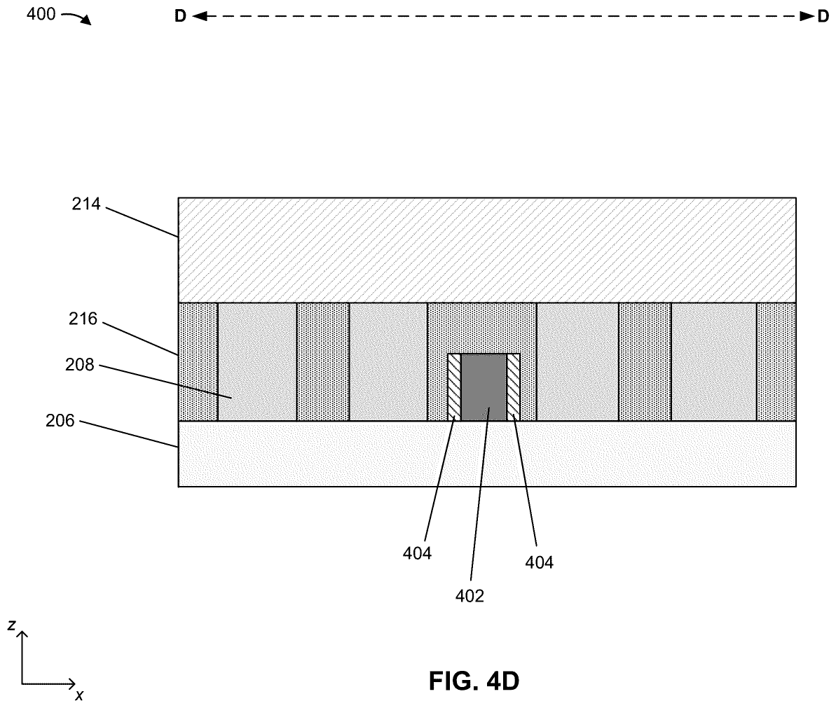

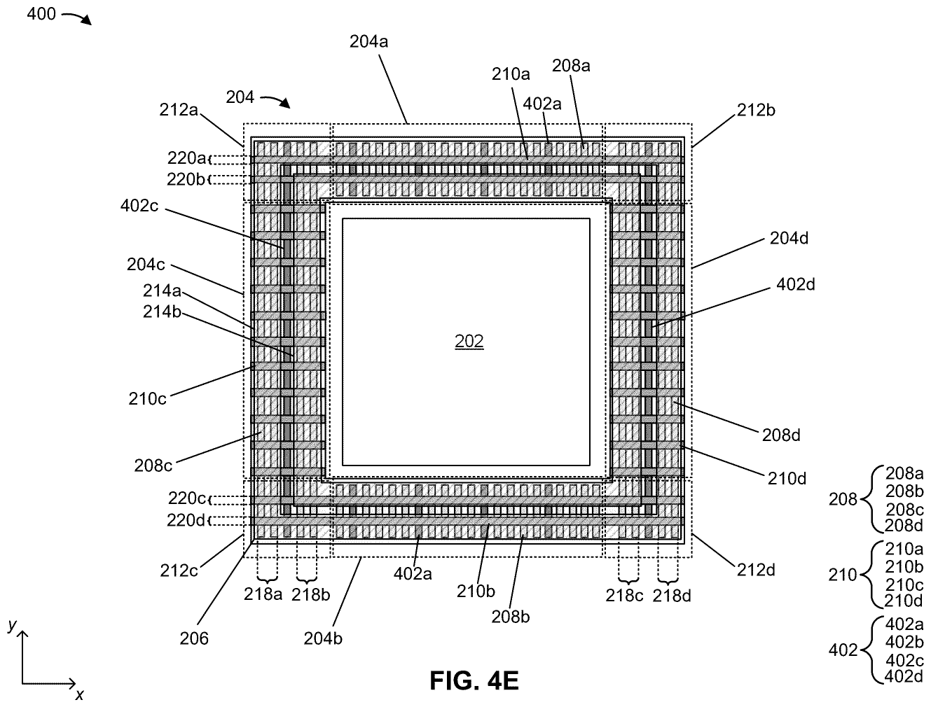

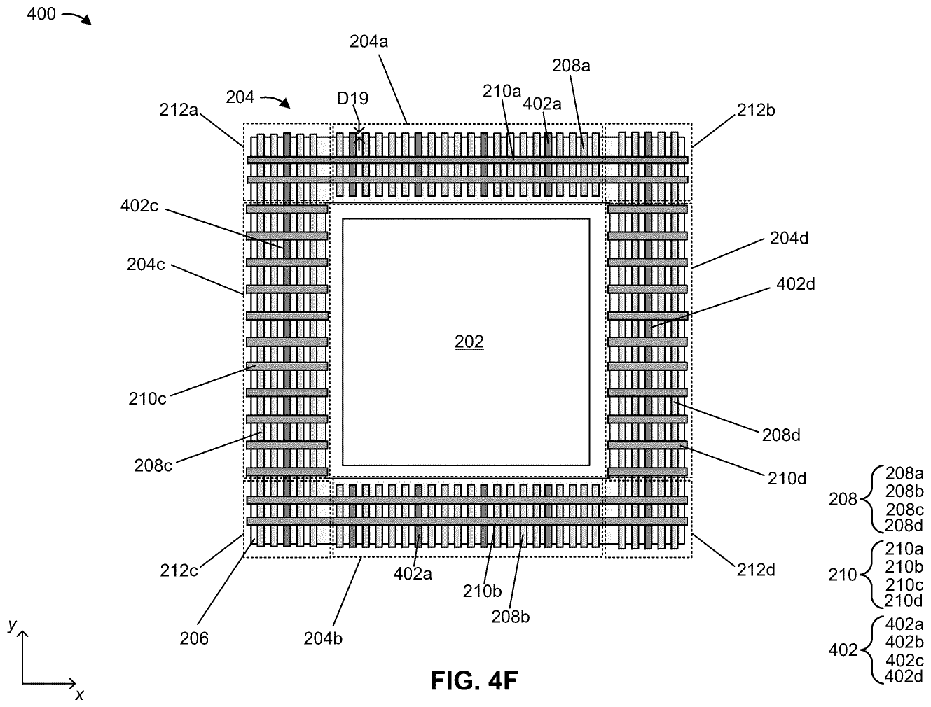

FIGS. 4A-4F are diagrams of example implementations of a semiconductor device 400 described herein. The semiconductor device 400 includes an example of a semiconductor device, such as a microprocessor, a memory device, an image sensor, and/or an RF device, among other examples.

FIGS. 4A and 4B illustrate top-down views of an example implementation of the semiconductor device 400. The example implementation of the semiconductor device 400 illustrated in FIGS. 4A and 4B is similar to the example implementation of the semiconductor device 200 illustrated in FIGS. 2A-2D, except that the edges of the example implementation of the semiconductor device 400 further include a plurality of polysilicon structures 402. The polysilicon structures 402 may be formed during the same semiconductor processing operations in which the gate structures (or dummy gate structures) of the transistors in the integrated circuit 202 are formed.

The polysilicon structures 402 may be included in the guard ring structure 204 to reduce, minimize, and/or prevent dishing in the guard ring structure 204. Dishing may occur in the dielectric layer from which the dielectric regions 216 are formed. In particular, dishing may occur during a planarization operation (or a CMP operation) to planarize the dielectric layer, and dishing may occur in regions in the dielectric layer between the gate structures of the semiconductor device 400. As the spacing between gate structures in the semiconductor device 400 increases, the likelihood and/or magnitude of dishing in this dielectric layer increases. The inclusion of the polysilicon structures 402 in the guard ring structure 204 reduces the distance of polysilicon structures between adjacent integrated circuits 202 of the semiconductor device 400, which may reduce the likelihood and/or magnitude of dishing in the dielectric layer.

As shown in FIGS. 4A and 4B, the polysilicon structures 402 extend in the y-direction and are arranged in the x-direction, similar to the conductive structures 208. The polysilicon structures 402 and the conductive structures 208 may be approximately parallel, and the polysilicon structures 402 and the conductive structures 210 may be approximately perpendicular. The polysilicon structures 402 may be formed of a polysilicon material and/or another suitable material.

The polysilicon structures 402 include one or more polysilicon structures 402a in the segment 204a of the guard ring structure 204, one or more polysilicon structures 402b in the segment 204b of the guard ring structure 204, one or more polysilicon structures 402c in the segment 204c of the guard ring structure 204, and/or one or more polysilicon structures 402d in the segment 204d of the guard ring structure 204. The polysilicon structure(s) 402c may extend into the corner regions 212a and 212c where the polysilicon structure(s) 402c intersect with the conductive structures 210a and 210b, respectively. The polysilicon structure(s) 402d may extend into the corner regions 212b and 212d where the polysilicon structure(s) 402d intersect with the conductive structures 210a and 210b, respectively.

The polysilicon structures 402a may be located between two or more of the conductive structures 208a and may intersect with the conductive structures 210a. The polysilicon structures 402b may be located between two or more of the conductive structures 208b and may intersect with the conductive structures 210b. The polysilicon structures 402c may be located between two or more of the conductive structures 208c and may intersect with the conductive structures 210c. A polysilicon structure 402c in the segment 204c may be located between subsets 218a and 218b of the conductive structures 208c. A polysilicon structure 402d in the segment 204d may be located between subsets 218c and 218d of the conductive structures 208d and may intersect with the conductive structures 210d. In some implementations, the segment 204c includes a quantity of polysilicon structures 402c that are included in a range from 1 to 4. However, other values for the range are within the scope of the present disclosure. The polysilicon structures 402d may be located between two or more of the conductive structures 208d. In some implementations, the segment 204d includes a quantity of polysilicon structures 402d that are included in a range from 1 to 4. However, other values for the range are within the scope of the present disclosure.

A y-direction length of the polysilicon structures 402a and, in some implementations, a y-direction length of the polysilicon structures 402b (corresponding to dimension D16) may be less than the y-direction width of the active region 206 in the segments 204a and 204b (e.g., the dimension D1). Thus, the polysilicon structures 402a and/or 402b are fully contained within a top view footprint of the active region 206 in the example implementation illustrated in FIGS. 4A and 4B.

A distance between an end of a polysilicon structure 402a and an edge of the active region 206 in the segment 204a (corresponding to dimension D17), and/or a distance between an end of a polysilicon structure 402b and an edge of the active region 206 in the segment 204b, may be included in a range of approximately 0.01 microns to approximately 1 micron. However, other values for the range are within the scope of the present disclosure.

Additionally and/or alternatively, at least a subset of the polysilicon structures 402a and/or at least a subset of the polysilicon structures 402b may have a y-direction length that is approximately equal to the y-direction width of the active region 206 in the segments 204a and/or 204b (e.g., dimension D17 may be approximately equal to dimension D16).

A y-direction length of the polysilicon structures 402c and, in some implementations, a y-direction length of the polysilicon structures 402d may be greater than the y-direction length of the polysilicon structures 402a and/or 402b. An x-direction width of the polysilicon structures 402 (corresponding to dimension D18) may be included in a range of approximately 0.01 microns to approximately 1 micron. However, other values for the range are within the scope of the present disclosure.

As shown in FIG. 4B, an interconnect structure 214 is included above the guard ring structure 204 around the integrated circuit 202. In the example implementation in FIGS. 4A and 4B, the polysilicon structures 402 are fully contained within the top view footprint of the interconnect structure 214.

FIGS. 4C and 4D illustrate cross-sectional views of the example implementation of the semiconductor device 400 in FIGS. 4A and 4B. FIG. 4C illustrates a cross-sectional view along a line C-C in FIG. 4B. FIG. 4D illustrates a cross-sectional view along a line D-D in FIG. 4B.

As shown in FIG. 4C, in regions of the semiconductor device 400 in which a polysilicon structure 402 intersects with a conductive structure 210, the polysilicon structure 402 is located under a conductive structure 210. The conductive structure 210 wraps around the polysilicon structure 402 on at least three sides of the polysilicon structure 402. As shown in FIG. 4D, in regions of the semiconductor device 400 in which a polysilicon structure 402 does not intersect with a conductive structure 210, the polysilicon structure 402 is located under a dielectric region 216. The dielectric region 216 wraps around the polysilicon structure 402 on at least three sides of the polysilicon structure 402.

As further shown in FIGS. 4C and 4D, sidewall spacers 404 may be included on sidewalls of the polysilicon structure 402. The sidewall spacers 404 may include one or more dielectric materials such as a silicon oxycarbide (SiOC), a silicon nitride (SiₓN_{y} such as Si₃N₄), and/or another suitable dielectric layer. The sidewall spacers 404 may be formed during the same set of semiconductor processing operations in which gate spacers of the gate structures of the transistors in the integrated circuit 202 are formed.

FIG. 4E illustrates a top-down view of another example implementation of the semiconductor device 400. The example implementation of the semiconductor device 400 illustrated in FIG. 4E is similar to the example implementation of the semiconductor device 400 illustrated in FIGS. 4A-4D, except that a plurality of interconnect structures 214a and 214b are included above the guard ring structure 204.

The interconnect structure 214a is located above portions of the polysilicon structures 402a in the segment 204a of the guard ring structure 204, and the interconnect structure 214b is located above other portions of the polysilicon structures 402a in the segment 204a of the guard ring structure 204. The interconnect structure 214a is located above portions of the polysilicon structures 402b in the segment 204b of the guard ring structure 204, and the interconnect structure 214b is located above other portions of the polysilicon structures 402b in the segment 204b of the guard ring structure 204. The polysilicon structures 402c may be located between the interconnect structures 214a and 214b in the segment 204c of the guard ring structure 204. The polysilicon structures 402d may be located between the interconnect structures 214a and 214b in the segment 204d of the guard ring structure 204. The interconnect structure 214a may be located over a portion of the polysilicon structures 402c in the corner regions 212a and 212c of the guard ring structure 204. The interconnect structure 214a may be located over a portion of the polysilicon structures 402d in the corner regions 212a and 212c of the guard ring structure 204.

FIG. 4F illustrates a top-down view of another example implementation of the semiconductor device 400. The example implementation of the semiconductor device 400 illustrated in FIG. 4F is similar to the example implementation of the semiconductor device 200 illustrated in FIGS. 4A-4D, except that one or more of the polysilicon structures 402, one or more of the conductive structures 208, and/or one or more of the conductive structures 210 extend laterally outward past the edges of the active region 206. A polysilicon structure 402 may extend laterally outward past an edge of the active region 206 by a distance (corresponding to dimension D19) that is included in a range of approximately 0.01 microns to approximately 1 micron. However, other values for the range are within the scope of the present disclosure.

As indicated above, FIGS. 4A-4F are provided as examples. Other examples may differ from what is described with regard to FIGS. 4A-4F.

FIGS. 5A-5E are diagrams of an example implementation 500 of forming a guard ring of a semiconductor device 400 described herein. The operations and/or techniques described in connection with the example implementation 500 may be performed to form one or more of the example implementations of the semiconductor device 400 illustrated and described in connection with FIGS. 4A-4D, 4E, and/or 4F, among other examples. In some implementations, one or more of the semiconductor processing operations described in connection with FIGS. 5A-5E may be performed using one or more of the semiconductor processing tools 102-112 and/or the wafer/die transport tool 114. In some implementations, one or more of the semiconductor processing operations described in connection with FIGS. 5A-5E may be performed using another semiconductor processing tool.

As shown in FIG. 5A, the active region 206 of the guard ring structure 204 is provided around the integrated circuit 202 of the semiconductor device 400. In some implementations, the active region 206 is provided as a portion of a substrate of the semiconductor device 400. In some implementations, the active region 206 is formed by doping the substrate around the integrated circuit 202 with one or more types of dopants. For example, an ion implantation tool 112 may be used to implant dopants in the substrate around the integrated circuit 202 using an ion implantation technique and/or another type of technique to form the active region 206. In some implementations, a deposition tool 102 may be used to deposit the active region 206 using a PVD technique, an ALD technique, a CVD technique, an epitaxy technique, another type of deposition technique described in connection with FIG. 1, and/or another suitable deposition technique.

As shown in FIG. 5B, the polysilicon structures 402 are formed over and/or on the active region 206. The polysilicon structures 402 are formed such that the polysilicon structures 402 are arranged in the x-direction and extend in the y-direction in the semiconductor device 400. A deposition tool 102 may be used to deposit the polysilicon structures 402 using a CVD technique, a PVD technique, an ALD technique, another deposition technique described above in connection with FIG. 1, and/or another suitable deposition technique.

As shown in FIG. 5C, the conductive structures 210 are formed over and/or on the active region 206, and over and/or on the polysilicon structures 402. The conductive structures 210 are formed such that the conductive structures 210 are arranged in the y-direction and extend in the x-direction in the semiconductor device 400.

A deposition tool 102 may be used to deposit the conductive structures 210 using a CVD technique, a PVD technique, an ALD technique, an electroplating technique, another deposition technique described above in connection with FIG. 1, and/or another suitable deposition technique. The conductive structures 210 may be deposited in one or more deposition operations. In some implementations, a seed layer is first deposited, and the conductive structures 210 are deposited on the seed layer. In some implementations, a planarization tool 110 may be used to planarize the conductive structures 210 after the conductive structures 210 are deposited.

In some implementations, a deposition tool 102 is used to form a dielectric layer, a deposition tool 102, an exposure tool 104, and a developer tool 106 are used to form a patterned masking layer on the dielectric layer, and an etch tool 108 is used to etch the dielectric layer based on the patterned masking layer to form the dielectric regions 216. The conductive structures 210 may then be formed in between the dielectric regions 216.

As shown in FIG. 5D, the conductive structures 208 are formed over and/or on the active region 206. The conductive structures 208 are formed such that the conductive structures 208 are arranged in the x-direction and extend in the y-direction in the semiconductor device 400. Moreover, the conductive structures 208 are formed such that the conductive structures 208 and the conductive structures 210 intersect to form a conductive grid above the active region 206. At least a subset of the conductive structures 208 are formed adjacent to opposing sides of one or more polysilicon structures 402.

A deposition tool 102 may be used to deposit the conductive structures 208 using a CVD technique, a PVD technique, an ALD technique, an electroplating technique, another deposition technique described above in connection with FIG. 1, and/or another suitable deposition technique. The conductive structures 208 may be deposited in one or more deposition operations. In some implementations, a seed layer is first deposited, and the conductive structures 208 are deposited on the seed layer. In some implementations, a planarization tool 110 may be used to planarize the conductive structures 208 after the conductive structures 208 are deposited.

In some implementations, a deposition tool 102 is used to form a dielectric layer, a deposition tool 102, an exposure tool 104, and a developer tool 106 are used to form a patterned masking layer on the dielectric layer, and an etch tool 108 is used to etch the dielectric layer based on the patterned masking layer to form the dielectric regions 216. The conductive structures 208 may then be formed in between the dielectric regions 216.

As shown in FIG. 5E, an interconnect structure 214 is formed over and/or on the guard ring structure 204 such that the interconnect structure 214 is physically coupled and/or electrically coupled with the conductive structures 208 and the conductive structures 210. In some implementations, a plurality of interconnect structures 214a and 214b are formed over and/or on the guard ring structure 204 such that the interconnect structures 214a and 214b are spaced apart and are not in physical contact with one another.

A deposition tool 102 may be used to deposit the interconnect structure(s) 214 using a CVD technique, a PVD technique, an ALD technique, an electroplating technique, another deposition technique described above in connection with FIG. 1, and/or another suitable deposition technique. The interconnect structure(s) 214 may be deposited in one or more deposition operations. In some implementations, a seed layer is first deposited, and the interconnect structure(s) 214 are deposited on the seed layer. In some implementations, a planarization tool 110 may be used to planarize the interconnect structure(s) 214 after the interconnect structure(s) 214 are deposited.

In some implementations, a deposition tool 102 is used to form a dielectric layer, a deposition tool 102, an exposure tool 104, and a developer tool 106 are used to form a patterned masking layer on the dielectric layer, and an etch tool 108 is used to etch the dielectric layer based on the patterned masking layer to form the dielectric regions 222. The interconnect structure(s) 214 may then be formed in between the dielectric regions 222.

As indicated above, FIGS. 5A-5E are provided as an example. Other examples may differ from what is described with regard to FIGS. 5A-5E.

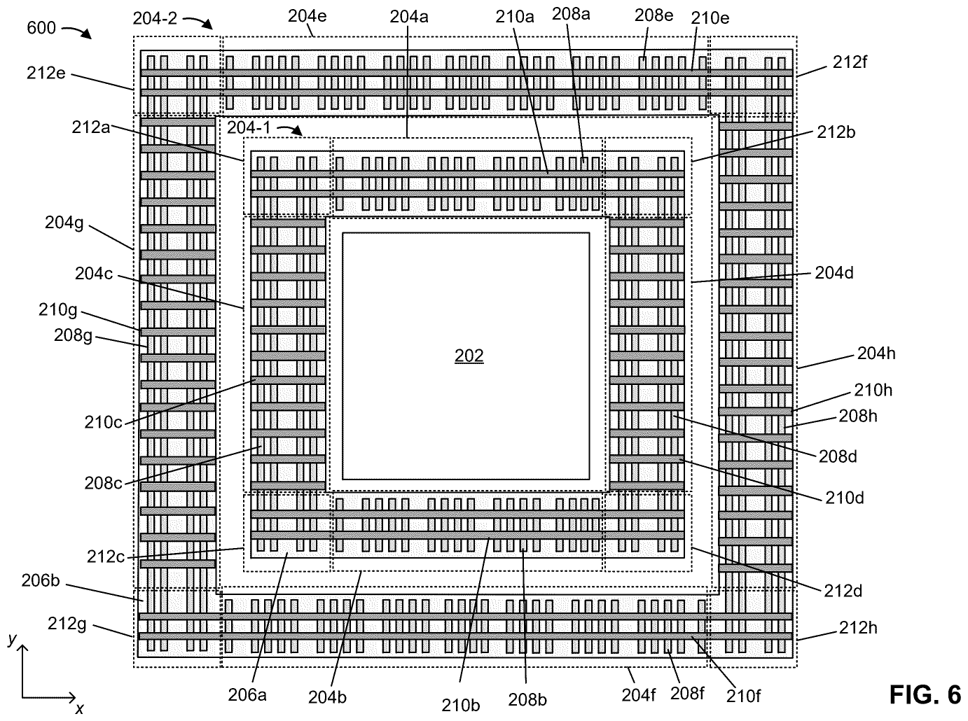

FIG. 6 is a diagram of an example implementation of a semiconductor device 600 described herein. The semiconductor device 600 includes an example of a semiconductor device, such as a microprocessor, a memory device, an image sensor, and/or an RF device, among other examples. FIG. 6 illustrates a top-down view of the example implementation of the semiconductor device 600. The example implementation of the semiconductor device 600 illustrated in FIG. 6 is similar to the example implementations of the semiconductor device 200 illustrated in FIGS. 2A-2I, except that the semiconductor device 600 includes a plurality of guard ring structures around the integrated circuit 202. For example, the semiconductor device 600 includes a guard ring structure 204-1 (e.g., an inner guard ring) around the integrated circuit 202, and a guard ring structure 204-2 (e.g., an outer guard ring) around the guard ring structure 204-1.

Including a plurality of guard ring structures around the integrated circuit 202 provides additional charge carrier absorption around the integrated circuit 202, and therefore provides increased latch-up protection. However, the single guard ring implementations described herein may be formed using less complex semiconductor manufacturing processes, and therefore consume fewer semiconductor manufacturing resources.

As shown in FIG. 6, the guard ring structure 204-1 includes a plurality of segments 204a, 204b, 204c, and/or 204d, and a plurality of corner regions 212a, 212b, 212c, and/or 212d. The guard ring structure 204-1 includes an active region 206a, a plurality of conductive structures 208 (e.g., conductive structures 208a, 208b, 208c, and/or 208d) arranged in the x-direction and extending in the y-direction, and a plurality of conductive structures 210 (e.g., conductive structures 210a, 210b, 210c, and/or 210d) arranged in the y-direction and extending in the x-direction. The guard ring structure 204-1 additionally includes one or more interconnect structures (e.g., an interconnect structure 214, interconnect structures 214a and 214b) that are not shown in FIG. 6 for the purpose of clarity. The guard ring structure 204-1 and/or the interconnect structure(s) 214 may be arranged according to any of the example implementations illustrated in FIGS. 2A-2I.

As further shown in FIG. 6, the guard ring structure 204-2 includes a plurality of segments 204e, 204f, 204g, and/or 204h, and a plurality of corner regions 212e, 212f, 212g, and/or 212h. The guard ring structure 204-2 includes an active region 206b, a plurality of conductive structures 208 (e.g., conductive structures 208e, 208f, 208g, and/or 208h) arranged in the x-direction and extending in the y-direction, and a plurality of conductive structures 210 (e.g., conductive structures 210e, 210f, 210g, and/or 210h) arranged in the y-direction and extending in the x-direction. The guard ring structure 204-2 additionally includes one or more interconnect structures (e.g., an interconnect structure 214, interconnect structures 214a and 214b) that are not shown in FIG. 6 for the purpose of clarity. The guard ring structure 204-2 and/or the interconnect structure(s) 214 may be arranged according to any of the example implementations illustrated in FIGS. 2A-2I.

In some implementations, the guard ring structures 204-1 and 204-2 are arranged in similar configurations. For example, the guard ring structures 204-1 and 204-2 may each be arranged according to the example implementation illustrated in FIGS. 2A-2D. In some implementations, the guard ring structures 204-1 and 204-2 are arranged in different configurations. For example, the guard ring structure 204-1 may be arranged according to the example implementation illustrated in FIG. 2E, and the guard ring structure 204-2 may be arranged according to the example implementation illustrated in FIGS. 2F-2H.

As indicated above, FIG. 6 is provided as an example. Other examples may differ from what is described with regard to FIG. 6.

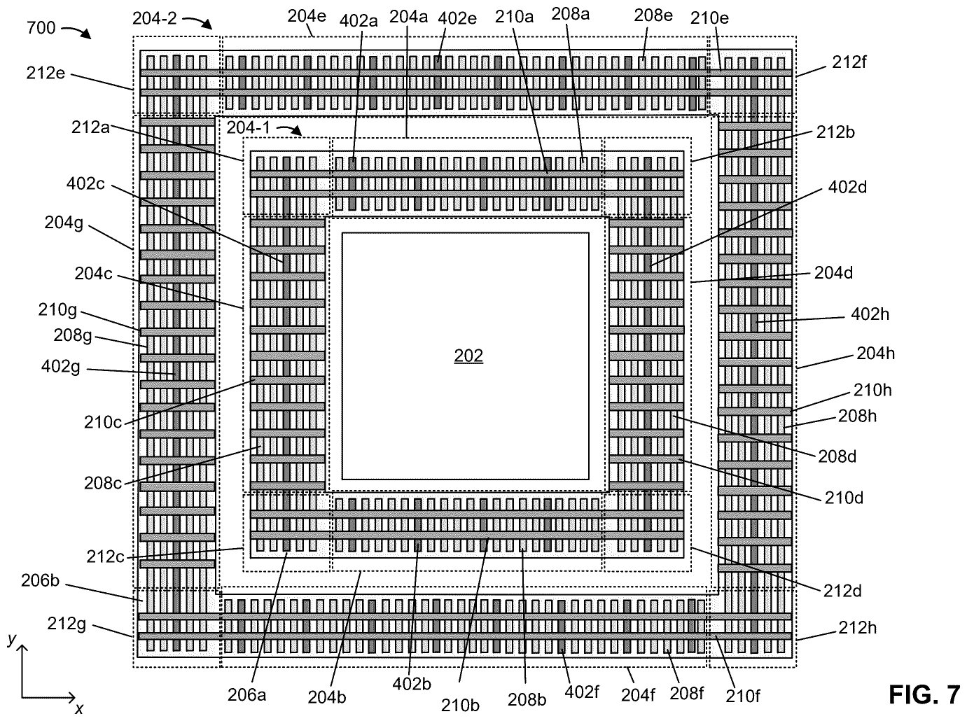

FIG. 7 is a diagram of an example implementation of a semiconductor device 700 described herein. The semiconductor device 700 includes an example of a semiconductor device, such as a microprocessor, a memory device, an image sensor, and/or an RF device, among other examples. FIG. 7 illustrates a top-down view of the example implementation of the semiconductor device 700. The example implementation of the semiconductor device 700 illustrated in FIG. 7 is similar to the example implementations of the semiconductor device 400 illustrated in FIGS. 4A-4F, except that the semiconductor device 700 includes a plurality of guard ring structures around the integrated circuit 202. For example, the semiconductor device 700 includes a guard ring structure 204-1 (e.g., an inner guard ring) around the integrated circuit 202, and a guard ring structure 204-2 (e.g., an outer guard ring) around the guard ring structure 204-1. The guard ring structure 204-1 and/or the guard ring structure 204-2 may further include a plurality of polysilicon structures 402.

Including a plurality of guard ring structures around the integrated circuit 202 provides additional charge carrier absorption around the integrated circuit 202, and therefore provides increased latch-up protection. However, the single guard ring implementations described herein may be formed using less complex semiconductor manufacturing processes, and therefore consume fewer semiconductor manufacturing resources. Additionally, the polysilicon structures 402 in the guard ring structure 204-1 and/or in the guard ring structure 204-2 may reduce the likelihood of dishing in a dielectric layer above the guard ring structure 204-1 and/or above the guard ring structure 204-2.

As shown in FIG. 7, the guard ring structure 204-1 includes a plurality of segments 204a, 204b, 204c, and/or 204d, and a plurality of corner regions 212a, 212b, 212c, and/or 212d. The guard ring structure 204-1 includes an active region 206a, a plurality of conductive structures 208 (e.g., conductive structures 208a, 208b, 208c, and/or 208d) arranged in the x-direction and extending in the y-direction, and a plurality of conductive structures 210 (e.g., conductive structures 210a, 210b, 210c, and/or 210d) arranged in the y-direction and extending in the x-direction. The guard ring structure 204-1 includes a plurality of polysilicon structures 402 (e.g., polysilicon structures 402a, 402b, 402c, and/or 402d arranged in the x-direction and extending in the y-direction. The guard ring structure 204-1 additionally includes one or more interconnect structures (e.g., an interconnect structure 214, interconnect structures 214a and 214b) that are not shown in FIG. 7 for the purpose of clarity. The guard ring structure 204-1 and/or the interconnect structure(s) 214 may be arranged according to any of the example implementations illustrated in FIGS. 4A-4F.

As further shown in FIG. 7, the guard ring structure 204-2 includes a plurality of segments 204e, 204f, 204g, and/or 204h, and a plurality of corner regions 212e, 212f, 212g, and/or 212h. The guard ring structure 204-2 includes an active region 206b, a plurality of conductive structures 208 (e.g., conductive structures 208e, 208f, 208g, and/or 208h) arranged in the x-direction and extending in the y-direction, and a plurality of conductive structures 210 (e.g., conductive structures 210e, 210f, 210g, and/or 210h) arranged in the y-direction and extending in the x-direction. The guard ring structure 204-2 includes a plurality of polysilicon structures 402 (e.g., polysilicon structures 402e, 402f, 402g, and/or 402h arranged in the x-direction and extending in the y-direction. The guard ring structure 204-2 additionally includes one or more interconnect structures (e.g., an interconnect structure 214, interconnect structures 214a and 214b) that are not shown in FIG. 7 for the purpose of clarity. The guard ring structure 204-2 and/or the interconnect structure(s) 214 may be arranged according to any of the example implementations illustrated in FIGS. 4A-4F.

In some implementations, the guard ring structures 204-1 and 204-2 are arranged in similar configurations. For example, the guard ring structures 204-1 and 204-2 may each be arranged according to the example implementation illustrated in FIGS. 4A-4D. In some implementations, the guard ring structures 204-1 and 204-2 are arranged in different configurations. For example, the guard ring structure 204-1 may be arranged according to the example implementation illustrated in FIG. 4E, and the guard ring structure 204-2 may be arranged according to the example implementation illustrated in FIG. 4F.

As indicated above, FIG. 7 is provided as an example. Other examples may differ from what is described with regard to FIG. 7.

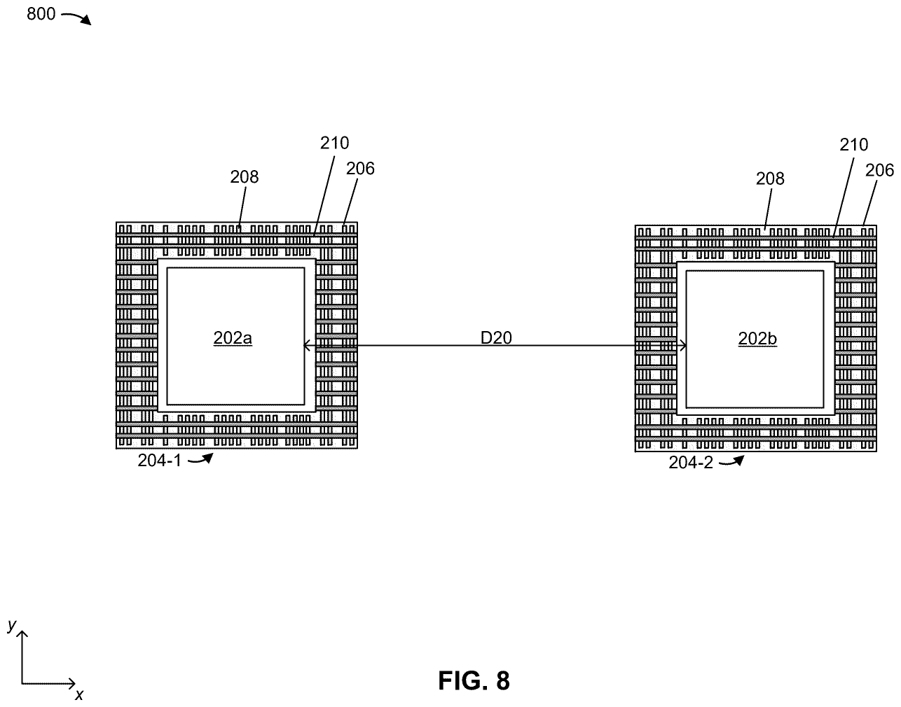

FIG. 8 is a diagram of an example implementation of a semiconductor device 800 described herein. The semiconductor device 800 includes an example of a semiconductor device, such as a microprocessor, a memory device, an image sensor, and/or an RF device, among other examples. FIG. 8 illustrates a top-down view of the example implementation of the semiconductor device 800. The example implementation of the semiconductor device 800 illustrated in FIG. 8 is similar to the example implementations of the semiconductor device 200 illustrated in FIGS. 2A-2I, except that the semiconductor device 800 includes a plurality of integrated circuits 202a and 202b. Respective guard ring structures 204 are included around each of the integrated circuits 202a and 202b. For example, the semiconductor device 800 includes a guard ring structure 204-1 around the integrated circuit 202a, and a guard ring structure 204-2 around the integrated circuit 202b.

Including a plurality of guard ring structures around each of the integrated circuits 202a and 202b provides charge carrier absorption for complementary metal oxide semiconductor (CMOS) circuitry of the semiconductor device 800. For example, the integrated circuit 202a may include a p-type metal oxide semiconductor (PMOS) integrated circuit (e.g., an integrated circuit that includes PMOS transistor(s)), and the integrated circuit 202b may include an n-type metal oxide semiconductor (NMOS) integrated circuit (e.g., an integrated circuit that includes NMOS transistor(s)). The guard ring structures 204-1 and 204-2 absorb charge carriers around the integrated circuits 202a and 202b, which prevents or reduces the likelihood of formation of a low-impedance path between the integrated circuits 202a and 202b through a substrate of the semiconductor device 800. Thus, the guard ring structures 204-1 and 204-2 prevent or reduce the likelihood of electrical shorting between the integrated circuits 202a and 202b (which might otherwise result in latch-up of the integrated circuits 202a and 202b). Moreover, the conductive grids formed in the guard ring structures 204-1 and 204-2 by the conductive structures 208 and 210 provide increased charge carrier absorption (e.g., due to the increased surface area coverage of the active regions 206 by the conductive structures 208 and 210) without increasing a distance between the integrated circuits 202a and 202b (corresponding to a dimension D20). Thus, the guard ring structures 204-1 and 204-2 enable the size of the semiconductor device 800 to be maintained or decreased.

As shown in FIG. 8, the guard ring structure 204-1 includes an active region 206, a plurality of conductive structures 208 above the active region 206 of the guard ring structure 204-1, and a plurality of conductive structures 210 above the active region 206 of the guard ring structure 204-1. The plurality of conductive structures 208 are arranged in the x-direction and extend in the y-direction. The plurality of conductive structures 210 are arranged in the y-direction and extend in the x-direction. The guard ring structure 204-1 additionally includes one or more interconnect structures (e.g., an interconnect structure 214, interconnect structures 214a and 214b) that are not shown in FIG. 8 for the purpose of clarity. The guard ring structure 204-1 and/or the interconnect structure(s) 214 may be arranged according to any of the example implementations illustrated in FIGS. 2A-2I.

The guard ring structure 204-2 includes an active region 206, a plurality of conductive structures 208 above the active region 206 of the guard ring structure 204-2, and a plurality of conductive structures 210 above the active region 206 of the guard ring structure 204-2. The plurality of conductive structures 208 are arranged in the x-direction and extend in the y-direction. The plurality of conductive structures 210 are arranged in the y-direction and extend in the x-direction. The guard ring structure 204-2 additionally includes one or more interconnect structures (e.g., an interconnect structure 214, interconnect structures 214a and 214b) that are not shown in FIG. 8 for the purpose of clarity. The guard ring structure 204-2 and/or the interconnect structure(s) 214 may be arranged according to any of the example implementations illustrated in FIGS. 2A-2I.

In some implementations, the guard ring structures 204-1 and 204-2 are arranged in similar configurations. For example, the guard ring structures 204-1 and 204-2 may each be arranged according to the example implementation illustrated in FIGS. 2A-2D. In some implementations, the guard ring structures 204-1 and 204-2 are arranged in different configurations. For example, the guard ring structure 204-1 may be arranged according to the example implementation illustrated in FIGS. 2A-2D, and the guard ring structure 204-2 may be arranged according to the example implementation illustrated in FIG. 2I.

As indicated above, FIG. 8 is provided as an example. Other examples may differ from what is described with regard to FIG. 8.

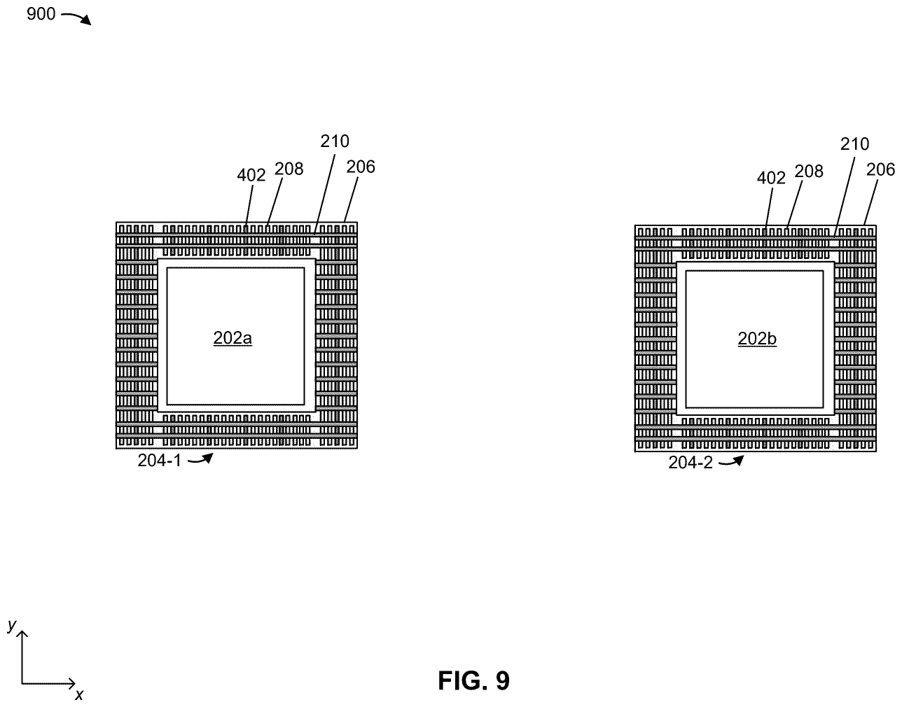

FIG. 9 is a diagram of an example implementation of a semiconductor device 900 described herein. The semiconductor device 900 includes an example of a semiconductor device, such as a microprocessor, a memory device, an image sensor, and/or an RF device, among other examples. FIG. 9 illustrates a top-down view of the example implementation of the semiconductor device 900. The example implementation of the semiconductor device 900 illustrated in FIG. 9 is similar to the example implementations of the semiconductor device 400 illustrated in FIGS. 4A-4F, except that the semiconductor device 900 includes a plurality of integrated circuits 202a and 202b. Respective guard ring structures 204 are included around each of the integrated circuits 202a and 202b. For example, the semiconductor device 900 includes a guard ring structure 204-1 around the integrated circuit 202a, and a guard ring structure 204-2 around the integrated circuit 202b. The guard ring structure 204-1 and/or the guard ring structure 204-2 may further include a plurality of polysilicon structures 402.

Including a plurality of guard ring structures around each of the integrated circuits 202a and 202b provides charge carrier absorption for CMOS circuitry of the semiconductor device 900. For example, the integrated circuit 202a may include a PMOS integrated circuit and the integrated circuit 202b may include an NMOS integrated circuit. The guard ring structures 204-1 and 204-2 absorb charge carriers around the integrated circuits 202a and 202b, which prevents or reduces the likelihood of formation of a low-impedance path between the integrated circuits 202a and 202b through a substrate of the semiconductor device 900. Thus, the guard ring structures 204-1 and 204-2 prevent or reduce the likelihood of electrical shorting between the integrated circuits 202a and 202b (which might otherwise result in latch-up of the integrated circuits 202a and 202b). Moreover, the conductive grids formed in the guard ring structures 204-1 and 204-2 by the conductive structures 208 and 210 provide increased charge carrier absorption (e.g., due to the increased surface area coverage of the active regions 206 by the conductive structures 208 and 210) without increasing a distance between the integrated circuits 202a and 202b. Thus, the guard ring structures 204-1 and 204-2 enable the size of the semiconductor device 900 to be maintained or decreased. Additionally, the polysilicon structures 402 in the guard ring structure 204-1 and/or in the guard ring structure 204-2 may reduce the likelihood of dishing in a dielectric layer above the guard ring structure 204-2 and/or above the guard ring structure 204-2.

As shown in FIG. 9, the guard ring structure 204-1 includes an active region 206, a plurality of conductive structures 208 above the active region 206 of the guard ring structure 204-1, a plurality of conductive structures 210 above the active region 206 of the guard ring structure 204-1, and a plurality of polysilicon structures 402 above the active region 206 of the guard ring structure 204-1. The plurality of conductive structures 208 are arranged in the x-direction and extend in the y-direction. The plurality of conductive structures 210 are arranged in the y-direction and extend in the x-direction. The plurality of polysilicon structures 402 are arranged in the x-direction and extend in the y-direction. The guard ring structure 204-1 additionally includes one or more interconnect structures (e.g., an interconnect structure 214, interconnect structures 214a and 214b) that are not shown in FIG. 9 for the purpose of clarity. The guard ring structure 204-1 and/or the interconnect structure(s) 214 may be arranged according to any of the example implementations illustrated in FIGS. 4A-4F.

The guard ring structure 204-2 includes an active region 206, a plurality of conductive structures 208 above the active region 206 of the guard ring structure 204-2, a plurality of conductive structures 210 above the active region 206 of the guard ring structure 204-2, and a plurality of polysilicon structures 402 above the active region 206 of the guard ring structure 204-2. The plurality of conductive structures 208 are arranged in the x-direction and extend in the y-direction. The plurality of conductive structures 210 are arranged in the y-direction and extend in the x-direction. The plurality of polysilicon structures 402 are arranged in the x-direction and extend in the y-direction. The guard ring structure 204-2 additionally includes one or more interconnect structures (e.g., an interconnect structure 214, interconnect structures 214a and 214b) that are not shown in FIG. 9 for the purpose of clarity. The guard ring structure 204-2 and/or the interconnect structure(s) 214 may be arranged according to any of the example implementations illustrated in FIGS. 4A-4F.

In some implementations, the guard ring structures 204-1 and 204-2 are arranged in similar configurations. For example, the guard ring structures 204-1 and 204-2 may each be arranged according to the example implementation illustrated in FIGS. 4A-4D. In some implementations, the guard ring structures 204-1 and 204-2 are arranged in different configurations. For example, the guard ring structure 204-1 may be arranged according to the example implementation illustrated in FIG. 4E, and the guard ring structure 204-2 may be arranged according to the example implementation illustrated in FIG. 4F.

As indicated above, FIG. 9 is provided as an example. Other examples may differ from what is described with regard to FIG. 9. For example, the guard ring structure 204-1 may be arranged according to an example implementation illustrated in FIGS. 2A-2I, and the guard ring structure 204-2 may be arranged according to an example implementation illustrated in FIGS. 4A-4F. As another example, the guard ring structure 204-2 may be arranged according to an example implementation illustrated in FIGS. 2A-2I, and the guard ring structure 204-1 may be arranged according to an example implementation illustrated in FIGS. 4A-4F.

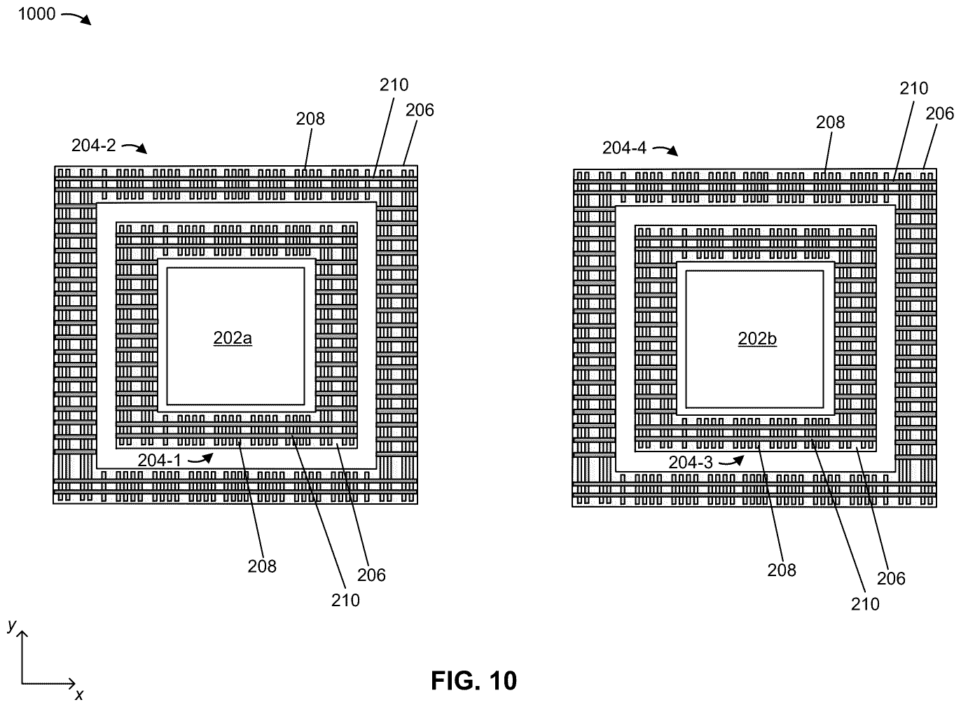

FIG. 10 is a diagram of an example implementation of a semiconductor device 1000 described herein. The semiconductor device 1000 includes an example of a semiconductor device, such as a microprocessor, a memory device, an image sensor, and/or an RF device, among other examples. FIG. 10 illustrates a top-down view of the example implementation of the semiconductor device 1000. The example implementation of the semiconductor device 1000 illustrated in FIG. 10 is similar to the example implementations of the semiconductor device 800 illustrates in FIG. 8, except that the semiconductor device 1000 includes a plurality of guard ring structures around one or more of the integrated circuits 202a and/or 202b, similar to the example embodiment illustrated in FIG. 6. For example, the semiconductor device 1000 may include a guard ring structure 204-1 (e.g., an inner guard ring) around the integrated circuit 202a, and a guard ring structure 204-2 (e.g., an outer guard ring) around the guard ring structure 204-1. As another example, the semiconductor device 1000 may include a guard ring structure 204-3 (e.g., an inner guard ring) around the integrated circuit 202b, and a guard ring structure 204-4 (e.g., an outer guard ring) around the guard ring structure 204-4. In some implementations, guard ring structures 204-1 and 204-2 are included around the integrated circuit 202a, and the guard ring structures 204-3 and 204-4 are included around the integrated circuit 202b.

Including a plurality of guard ring structures around the integrated circuits 202a and/or 202b provides additional charge carrier absorption around the integrated circuits 202a and/or 202b, and therefore provides increased latch-up protection for the semiconductor device 1000.

As shown in FIG. 10, the guard ring structure 204-1 includes an active region 206, a plurality of conductive structures 208 above the active region 206 of the guard ring structure 204-1, and a plurality of conductive structures 210 above the active region 206 of the guard ring structure 204-1. The plurality of conductive structures 208 are arranged in the x-direction and extend in the y-direction. The plurality of conductive structures 210 are arranged in the y-direction and extend in the x-direction. The guard ring structure 204-1 additionally includes one or more interconnect structures (e.g., an interconnect structure 214, interconnect structures 214a and 214b) that are not shown in FIG. 10 for the purpose of clarity. The guard ring structure 204-1 and/or the interconnect structure(s) 214 may be arranged according to any of the example implementations illustrated in FIGS. 2A-2I.

The guard ring structure 204-2 includes an active region 206, a plurality of conductive structures 208 above the active region 206 of the guard ring structure 204-2, and a plurality of conductive structures 210 above the active region 206 of the guard ring structure 204-2. The plurality of conductive structures 208 are arranged in the x-direction and extend in the y-direction. The plurality of conductive structures 210 are arranged in the y-direction and extend in the x-direction. The guard ring structure 204-2 additionally includes one or more interconnect structures (e.g., an interconnect structure 214, interconnect structures 214a and 214b) that are not shown in FIG. 10 for the purpose of clarity. The guard ring structure 204-2 and/or the interconnect structure(s) 214 may be arranged according to any of the example implementations illustrated in FIGS. 2A-2I.

The guard ring structure 204-3 includes an active region 206, a plurality of conductive structures 208 above the active region 206 of the guard ring structure 204-3, and a plurality of conductive structures 210 above the active region 206 of the guard ring structure 204-3. The plurality of conductive structures 208 are arranged in the x-direction and extend in the y-direction. The plurality of conductive structures 210 are arranged in the y-direction and extend in the x-direction. The guard ring structure 204-3 additionally includes one or more interconnect structures (e.g., an interconnect structure 214, interconnect structures 214a and 214b) that are not shown in FIG. 10 for the purpose of clarity. The guard ring structure 204-3 and/or the interconnect structure(s) 214 may be arranged according to any of the example implementations illustrated in FIGS. 2A-2I.

The guard ring structure 204-3 includes an active region 206, a plurality of conductive structures 208 above the active region 206 of the guard ring structure 204-4, and a plurality of conductive structures 210 above the active region 206 of the guard ring structure 204-4. The plurality of conductive structures 208 are arranged in the x-direction and extend in the y-direction. The plurality of conductive structures 210 are arranged in the y-direction and extend in the x-direction. The guard ring structure 204-4 additionally includes one or more interconnect structures (e.g., an interconnect structure 214, interconnect structures 214a and 214b) that are not shown in FIG. 10 for the purpose of clarity. The guard ring structure 204-4 and/or the interconnect structure(s) 214 may be arranged according to any of the example implementations illustrated in FIGS. 2A-2I.

In some implementations, two or more of the guard ring structures 204-1, 204-2, 204-3, and/or 204-4 are arranged in similar configurations. For example, two or more of the guard ring structure 204-1, 204-2, 204-3, and/or 204-4 may each be arranged according to the example implementation illustrated in FIGS. 2A-2D. In some implementations, two or more of the guard ring structures 204-1, 204-2, 204-3, and/or 204-4 are arranged in different configurations. For example, the guard ring structure 204-1 may be arranged according to the example implementation illustrated in FIG. 2E, and the guard ring structure 204-3 may be arranged according to the example implementation illustrated in FIGS. 2F-2H.

As indicated above, FIG. 10 is provided as an example. Other examples may differ from what is described with regard to FIG. 10.

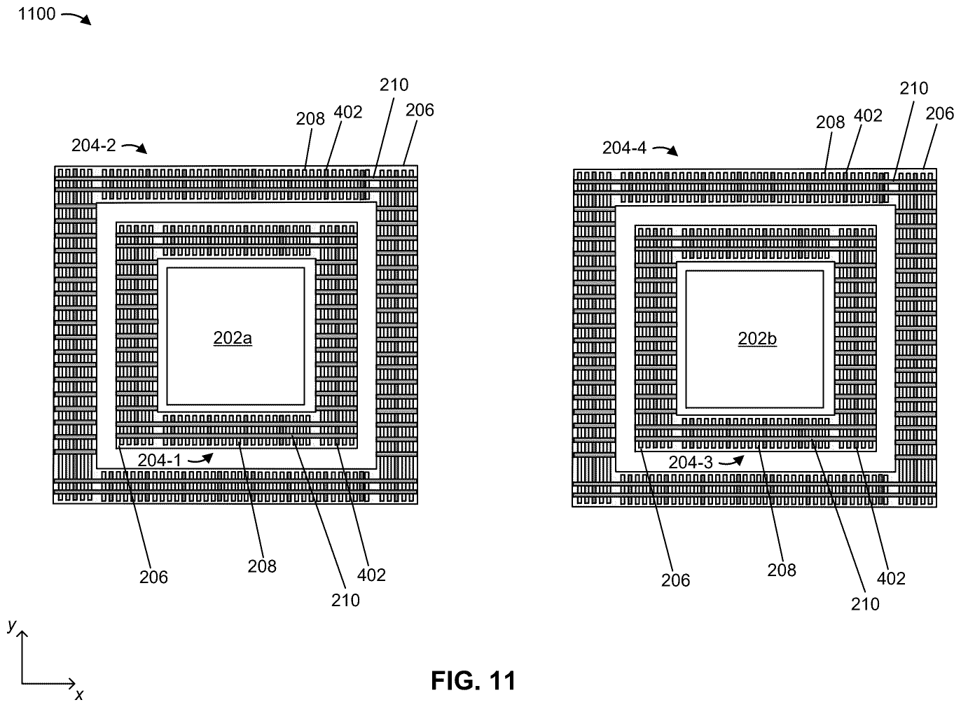

FIG. 11 is a diagram of an example implementation of a semiconductor device 1100 described herein. The semiconductor device 1100 includes an example of a semiconductor device, such as a microprocessor, a memory device, an image sensor, and/or an RF device, among other examples. FIG. 11 illustrates a top-down view of the example implementation of the semiconductor device 1100. The example implementation of the semiconductor device 1100 illustrated in FIG. 11 is similar to the example implementations of the semiconductor device 700 illustrates in FIG. 7, except that the semiconductor device 1100 includes a plurality of guard ring structures around the integrated circuit 202a and/or around the integrated circuit 202b. For example, the semiconductor device 1100 may include a guard ring structure 204-1 (e.g., an inner guard ring) around the integrated circuit 202a, and a guard ring structure 204-2 (e.g., an outer guard ring) around the guard ring structure 204-1. As another example, the semiconductor device 1100 may include a guard ring structure 204-3 (e.g., an inner guard ring) around the integrated circuit 202b, and a guard ring structure 204-4 (e.g., an outer guard ring) around the guard ring structure 204-3. In some implementations, guard ring structures 204-1 and 204-2 are included around the integrated circuit 202a, and the guard ring structures 204-3 and 204-4 are included around the integrated circuit 202b. One or more of the guard ring structures 204-1, 204-2, 204-3, and/or 204-4 may further include a plurality of polysilicon structures 402.

Including a plurality of guard ring structures around the integrated circuits 202a and/or 202b provides additional charge carrier absorption around the integrated circuits 202a and/or 202b, and therefore provides increased latch-up protection for the semiconductor device 1100. Additionally, the polysilicon structures 402 in the guard ring structures 204-1, 204-2, 204-3, and/or 204-4 may reduce the likelihood of dishing in a dielectric layer above the guard ring structures 204-1, 204-2, 204-3, and/or 204-4.

As shown in FIG. 11, the guard ring structure 204-1 includes an active region 206, a plurality of conductive structures 208 above the active region 206 of the guard ring structure 204-1, a plurality of conductive structures 210 above the active region 206 of the guard ring structure 204-1, and a plurality of polysilicon structures 402. The plurality of conductive structures 208 are arranged in the x-direction and extend in the y-direction. The plurality of conductive structures 210 are arranged in the y-direction and extend in the x-direction. The plurality of polysilicon structures 402 are arranged in the x-direction and extend in the y-direction. The guard ring structure 204-1 additionally includes one or more interconnect structures (e.g., an interconnect structure 214, interconnect structures 214a and 214b) that are not shown in FIG. 11 for the purpose of clarity. The guard ring structure 204-1 and/or the interconnect structure(s) 214 may be arranged according to any of the example implementations illustrated in FIGS. 4A-4F.

As shown in FIG. 11, the guard ring structure 204-2 includes an active region 206, a plurality of conductive structures 208 above the active region 206 of the guard ring structure 204-2, a plurality of conductive structures 210 above the active region 206 of the guard ring structure 204-2, and a plurality of polysilicon structures 402. The plurality of conductive structures 208 are arranged in the x-direction and extend in the y-direction. The plurality of conductive structures 210 are arranged in the y-direction and extend in the x-direction. The plurality of polysilicon structures 402 are arranged in the x-direction and extend in the y-direction. The guard ring structure 204-2 additionally includes one or more interconnect structures (e.g., an interconnect structure 214, interconnect structures 214a and 214b) that are not shown in FIG. 11 for the purpose of clarity. The guard ring structure 204-2 and/or the interconnect structure(s) 214 may be arranged according to any of the example implementations illustrated in FIGS. 4A-4F.

As shown in FIG. 11, the guard ring structure 204-3 includes an active region 206, a plurality of conductive structures 208 above the active region 206 of the guard ring structure 204-3, a plurality of conductive structures 210 above the active region 206 of the guard ring structure 204-3, and a plurality of polysilicon structures 402. The plurality of conductive structures 208 are arranged in the x-direction and extend in the y-direction. The plurality of conductive structures 210 are arranged in the y-direction and extend in the x-direction. The plurality of polysilicon structures 402 are arranged in the x-direction and extend in the y-direction. The guard ring structure 204-3 additionally includes one or more interconnect structures (e.g., an interconnect structure 214, interconnect structures 214a and 214b) that are not shown in FIG. 11 for the purpose of clarity. The guard ring structure 204-3 and/or the interconnect structure(s) 214 may be arranged according to any of the example implementations illustrated in FIGS. 4A-4F.

As shown in FIG. 11, the guard ring structure 204-4 includes an active region 206, a plurality of conductive structures 208 above the active region 206 of the guard ring structure 204-4, a plurality of conductive structures 210 above the active region 206 of the guard ring structure 204-4, and a plurality of polysilicon structures 402. The plurality of conductive structures 208 are arranged in the x-direction and extend in the y-direction. The plurality of conductive structures 210 are arranged in the y-direction and extend in the x-direction. The plurality of polysilicon structures 402 are arranged in the x-direction and extend in the y-direction. The guard ring structure 204-4 additionally includes one or more interconnect structures (e.g., an interconnect structure 214, interconnect structures 214a and 214b) that are not shown in FIG. 11 for the purpose of clarity. The guard ring structure 204-4 and/or the interconnect structure(s) 214 may be arranged according to any of the example implementations illustrated in FIGS. 4A-4F.

In some implementations, two or more of the guard ring structures 204-1, 204-2, 204-3, and/or 204-4 are arranged in similar configurations. For example, two or more of the guard ring structure 204-1, 204-2, 204-3, and/or 204-4 may each be arranged according to the example implementation illustrated in FIGS. 4A-4D. In some implementations, two or more of the guard ring structures 204-1, 204-2, 204-3, and/or 204-4 are arranged in different configurations. For example, the guard ring structure 204-2 may be arranged according to the example implementation illustrated in FIG. 4F, and the guard ring structure 204-4 may be arranged according to the example implementation illustrated in FIG. 5E.

As indicated above, FIG. 11 is provided as an example. Other examples may differ from what is described with regard to FIG. 11. For example, a single guard ring structure 204 may be included around the integrated circuit 202a, and a plurality of guard ring structures 204-3 and 204-4 may be included around the integrated circuit 202b, where the guard ring structures 204, 204-3, and 204-4 have the same configuration or different configurations according to the example implementations in FIGS. 2A-2I, 4A-4F, 6, and/or 7. As another example, a single guard ring structure 204 may be included around the integrated circuit 202b, and a plurality of guard ring structures 204-1 and 204-2 may be included around the integrated circuit 202a, where the guard ring structures 204, 204-1, and 204-2 have the same configuration or different configurations according to the example implementations in FIGS. 2A-2I, 4A-4F, 6, and/or 7. As another example, a plurality of guard ring structures 204-1 and 204-2 may be included around the integrated circuit 202a, and a plurality of guard ring structures 204-3 and 204-4 may be included around the integrated circuit 202d, where the guard ring structures 204-1, 204-2, 204-3, and 204-4 have the same configuration or different configurations according to the example implementations in FIGS. 2A-2I, 4A-4F, 6, and/or 7.

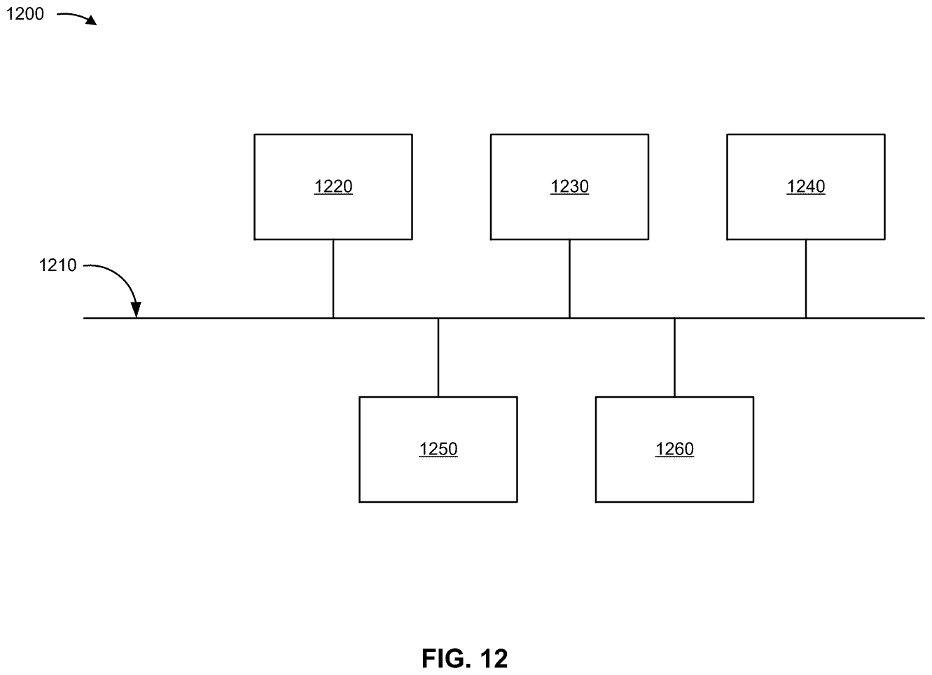

FIG. 12 is a diagram of example components of a device 1200 described herein. In some implementations, one or more of the semiconductor processing tools 102-112 and/or the wafer/die transport tool 114 may include one or more devices 1200 and/or one or more components of the device 1200. As shown in FIG. 12, the device 1200 may include a bus 1210, a processor 1220, a memory 1230, an input component 1240, an output component 1250, and/or a communication component 1260.

The bus 1210 may include one or more components that enable wired and/or wireless communication among the components of the device 1200. The bus 1210 may couple together two or more components of FIG. 12, such as via operative coupling, communicative coupling, electronic coupling, and/or electric coupling. For example, the bus 1210 may include an electrical connection (e.g., a wire, a trace, and/or a lead) and/or a wireless bus. The processor 1220 may include a central processing unit, a graphics processing unit, a microprocessor, a controller, a microcontroller, a digital signal processor, a field-programmable gate array, an application-specific integrated circuit, and/or another type of processing component. The processor 1220 may be implemented in hardware, firmware, or a combination of hardware and software. In some implementations, the processor 1220 may include one or more processors capable of being programmed to perform one or more operations or processes described elsewhere herein.

The memory 1230 may include volatile and/or nonvolatile memory. For example, the memory 1230 may include random access memory (RAM), read only memory (ROM), a hard disk drive, and/or another type of memory (e.g., a flash memory, a magnetic memory, and/or an optical memory). The memory 1230 may include internal memory (e.g., RAM, ROM, or a hard disk drive) and/or removable memory (e.g., removable via a universal serial bus connection). The memory 1230 may be a non-transitory computer-readable medium. The memory 1230 may store information, one or more instructions, and/or software (e.g., one or more software applications) related to the operation of the device 1200. In some implementations, the memory 1230 may include one or more memories that are coupled (e.g., communicatively coupled) to one or more processors (e.g., processor 1220), such as via the bus 1210. Communicative coupling between a processor 1220 and a memory 1230 may enable the processor 1220 to read and/or process information stored in the memory 1230 and/or to store information in the memory 1230.

The input component 1240 may enable the device 1200 to receive input, such as user input and/or sensed input. For example, the input component 1240 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1250 may enable the device 1200 to provide output, such as via a display, a speaker, and/or a light-emitting diode. The communication component 1260 may enable the device 1200 to communicate with other devices via a wired connection and/or a wireless connection. For example, the communication component 1260 may include a receiver, a transmitter, a transceiver, a modem, a network interface card, and/or an antenna.

The device 1200 may perform one or more operations or processes described herein. For example, a non-transitory computer-readable medium (e.g., memory 1230) may store a set of instructions (e.g., one or more instructions or code) for execution by the processor 1220. The processor 1220 may execute the set of instructions to perform one or more operations or processes described herein. In some implementations, execution of the set of instructions, by one or more processors 1220, causes the one or more processors 1220 and/or the device 1200 to perform one or more operations or processes described herein. In some implementations, hardwired circuitry may be used instead of or in combination with the instructions to perform one or more operations or processes described herein. Additionally, or alternatively, the processor 1220 may be configured to perform one or more operations or processes described herein. Thus, implementations described herein are not limited to any specific combination of hardware circuitry and software.

The number and arrangement of components shown in FIG. 12 are provided as an example. The device 1200 may include additional components, fewer components, different components, or differently arranged components than those shown in FIG. 12. Additionally, or alternatively, a set of components (e.g., one or more components) of the device 1200 may perform one or more functions described as being performed by another set of components of the device 1200.

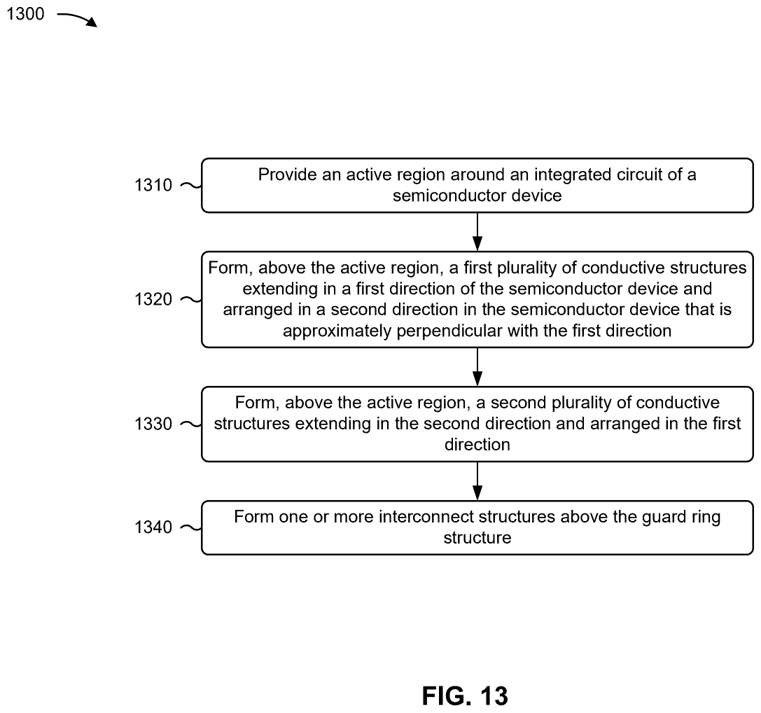

FIG. 13 is a flowchart of an example process 1300 associated with forming a semiconductor device described herein. In some implementations, one or more process blocks of FIG. 13 are performed using one or more semiconductor processing tools (e.g., one or more of the semiconductor processing tools 102-112 and/or the wafer/die transport tool 114). Additionally, or alternatively, one or more process blocks of FIG. 13 may be performed using one or more components of device 1200, such as processor 1220, memory 1230, input component 1240, output component 1250, and/or communication component 1260.

As shown in FIG. 13, process 1300 may include providing an active region around an integrated circuit device of a semiconductor device (block 1310). For example, one or more of the semiconductor processing tools 102-112 and/or the wafer/die transport tool 114 may be used to provide an active region (e.g., an active region 206, 206a, 206b, 206c, and/or 206d) around an integrated circuit (e.g., an integrated circuit 202, 202a, and/or 202b) of a semiconductor device (e.g., a semiconductor device 200, 400, 600, 700, 800, 900, and/or 1000), as described herein.

As further shown in FIG. 13, process 1300 may include forming, above the active region, a first plurality of conductive structures extending in a first direction of the semiconductor device and arranged in a second direction in the semiconductor device that is approximately perpendicular with the first direction (block 1320). For example, one or more of the semiconductor processing tools 102-112 may be used to form, above the active region, a first plurality of conductive structures (e.g., conductive structures 208, 208a, 208b, 208c, 208d, 208e, 208f, 208g, and/or 208h) extending in a first direction (e.g., a y-direction) of the semiconductor device and arranged in a second direction (e.g., an x-direction) in the semiconductor device that is approximately perpendicular with the first direction, as described herein.

As further shown in FIG. 13, process 1300 may include forming, above the active region, a second plurality of conductive structures extending in the second direction and arranged in the first direction (block 1330). For example, one or more of the semiconductor processing tools 102-112 may be used to form, above the active region, a second plurality of conductive structures (e.g., conductive structures 210, 210a, 210b, 210c, 210d, 210e, 210f, 210g, and/or 210h) extending in the second direction and arranged in the first direction, as described herein. In some implementations, the first plurality of conductive structures and the second plurality of conductive structures intersect to form a guard ring structure (e.g., guard ring structure 204, 204-1, 204-2, 204-3, and/or 204-4) above the active region.

As further shown in FIG. 13, process 1300 may include forming one or more interconnect structures above the guard ring structure (block 1340). For example, one or more of the semiconductor processing tools 102-112 may be used to form one or more interconnect structures (e.g., interconnect structures 214, 214a, and/or 214b) above the guard ring structure, as described herein.

Process 1300 may include additional implementations, such as any single implementation or any combination of implementations described below and/or in connection with one or more other processes described elsewhere herein.

In a first implementation, the active region is a first active region (e.g., an active region 206a) of the semiconductor device, the guard ring structure is a first guard ring structure (e.g., a guard ring structure 204-1, a guard ring structure 204-3) of the semiconductor device, and the process 1300 includes providing a second active region (e.g., an active region 206b) around the first active region, forming, above the second active region, a third plurality of conductive structures (e.g., conductive structures 208e, 208f, 208g, and/or 208h) extending in the first direction and arranged in the second direction, and forming, above the second active region, a fourth plurality of conductive structures (e.g., conductive structures 210e, 210f, 210g, and/or 210h) extending in the second direction and arranged in the first direction, where the third plurality of conductive structures and the fourth plurality of conductive structures intersect to form a second guard ring structure (e.g., a guard ring structure 204-2, a guard ring structure 204-4) above the second active region.

In a second implementation, alone or in combination with the first implementation, process 1300 includes forming a first a plurality of polysilicon structures (e.g., polysilicon structures 402a, polysilicon structures 402b) above the first active region, the first plurality of polysilicon structures extending in the first direction, and forming a second plurality of polysilicon structures (e.g., polysilicon structures 402a, polysilicon structures 402b) above the second active region, the second plurality of polysilicon structures extending in the first direction.

In a third implementation, alone or in combination with one or more of the first and second implementations, the integrated circuit is a first integrated circuit (e.g., an integrated circuit 202a) of the semiconductor device, the active region is a first active region (e.g., an active region 206a) of the semiconductor device, the guard ring structure is a first guard ring structure (e.g., a guard ring structure 204-1, a guard ring structure 204-3) of the semiconductor device, and the process 1300 includes providing a second active region (e.g., an active region 206a, and active region 206b) around a second integrated circuit (e.g., an integrated circuit 202b) that is adjacent to the first integrated circuit, forming, above the second active region, a third plurality of conductive structures (e.g., conductive structures 208) extending in the first direction and arranged in the second direction, and forming, above the second active region, a fourth plurality of conductive structures (e.g., conductive structures 210) extending in the second direction and arranged in the first direction, wherein the third plurality of conductive structures and the fourth plurality of conductive structures intersect to form a second guard ring structure (e.g., a guard ring structure 204-2, a guard ring structure 204-4) above the second active region.

In a fourth implementation, alone or in combination with one or more of the first through third implementations, process 1300 includes forming a first a plurality of polysilicon structures (e.g., polysilicon structures 402a, polysilicon structures 402b) above the first active region, where the first plurality of polysilicon structures extend in the first direction, and forming a second plurality of polysilicon structures (e.g., polysilicon structures 402a, polysilicon structures 402b) above the second active region, where the second plurality of polysilicon structures extend in the first direction.

In a fifth implementation, alone or in combination with one or more of the first through fourth implementations, process 1300 includes providing a third active region (e.g., an active region 206b) around the first active region, forming, above the third active region, a fifth plurality of conductive structures (e.g., conductive structure 208) extending in the first direction and arranged in the second direction, and forming, above the second active region, a sixth plurality of conductive structures (e.g., conductive structures 210) extending in the second direction and arranged in the first direction, where the fifth plurality of conductive structures and the sixth plurality of conductive structures intersect to form a third guard ring structure (e.g., a guard ring structure 204-2) above the first active region.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, a semiconductor device includes an integrated circuit and one or more guard rings around the integrated circuit in a top view of the semiconductor device. At least one guard ring of the one or more guard rings includes an active region in the substrate, a first plurality of elongated conductive structures extending in a first direction in the top view of the semiconductor device and arranged in a second direction in the top view of the semiconductor device, and a second plurality of elongated conductive structures extending in the second direction and arranged in the first direction. The combination of the first and second pluralities of elongated conductive structures forms a conductive grid above the active region, and provides increased coverage of the surface area of the active region relative to including only the first plurality of elongated conductive structures or only the second plurality of elongated conductive structures. The combination of the first and second pluralities of elongated conductive structures enables the coverage of the surface area to be increased in both the first direction and the second direction within a footprint or boundary of an interconnect structure above the first and second pluralities of conductive structures. In this way, the first and second pluralities of conductive structures enable a high amount of charge carrier absorption to be achieved in the semiconductor device (which may reduce the likelihood of latch-up in the semiconductor device) while enabling a short distance or spacing between adjacent integrated circuits in the semiconductor device to be achieved.

As described in greater detail above, some implementations described herein provide a semiconductor device. The semiconductor device includes an integrated circuit. The semiconductor device includes a guard ring structure surrounding the integrated circuit in a top view of the semiconductor device. The guard ring structure includes an active region a first plurality of conductive structures above the active region, where the first plurality of conductive structures extend in a first direction in the semiconductor device and are arranged in a second direction in the semiconductor device that is approximately perpendicular to the first direction a second plurality of conductive structures above the active region, where the second plurality of conductive structures extend in the second direction and are arranged in the first direction. The semiconductor device includes an interconnect structure above the guard ring structure.

As described in greater detail above, some implementations described herein provide a semiconductor device. The semiconductor device includes an integrated circuit. The semiconductor device includes a guard ring structure surrounding the integrated circuit in a top view of the semiconductor device. The guard ring structure includes a first plurality of conductive structures, where the first plurality of conductive structures extend in a first direction in the semiconductor device and are arranged in a second direction in the semiconductor device that is approximately perpendicular to the first direction. The guard ring structure includes a second plurality of conductive structures above the active region, where the second plurality of conductive structures extend in the second direction and are arranged in the first direction and a first length of a first subset of the second plurality of conductive structures is greater than a second length of a second subset of the second plurality of conductive structures. The guard ring structure includes plurality of polysilicon structures extending in the first direction, where each of the polysilicon structures is located between adjacent pairs of the first plurality of conductive structures. The semiconductor device includes a first interconnect structure above the guard ring structure, where at least a first subset of the first plurality of conductive structures is within a footprint of the first interconnect structure. The semiconductor device includes a second interconnect structure above the guard ring structure, where at least a second subset of the first plurality of conductive structures is within a footprint of the second interconnect structure.

As described in greater detail above, some implementations described herein provide a method. The method includes providing an active region around an integrated circuit of a semiconductor device. The method includes forming, above the active region, a first plurality of conductive structures extending in a first direction of the semiconductor device and arranged in a second direction in the semiconductor device that is approximately perpendicular with the first direction. The method includes forming, above the active region, a second plurality of conductive structures extending in the second direction and arranged in the first direction, where the first plurality of conductive structures and the second plurality of conductive structures intersect to form a guard ring structure above the active region. The method includes forming one or more interconnect structures above the guard ring structure.

The terms “approximately” and “substantially” can indicate a value of a given quantity or magnitude that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing an active region around an integrated circuit of a semiconductor device;
forming a first plurality of conductive structures above the active region,
wherein the first plurality of conductive structures extend in a first direction in the semiconductor device and are arranged in a second direction in the semiconductor device that is approximately perpendicular to the first direction; and
forming a second plurality of conductive structures above the active region,
wherein the second plurality of conductive structures extend in the second direction and are arranged in the first direction.

2. The method of claim 1, further comprising:
forming an interconnect structure above the active region.

3. The method of claim 2, wherein forming the first plurality of conductive structures comprises:
forming the first plurality of conductive structures such that an entirety of the first plurality of conductive structures is located within a footprint of the interconnect structure.

4. The method of claim 2, wherein forming the second plurality of conductive structures comprises:
forming the second plurality of conductive structures such that portions of the second plurality of conductive structures extend laterally outward from the interconnect structure.

5. The method of claim 1, wherein forming the first plurality of conductive structures comprises:
forming the first plurality of conductive structures such that the first plurality of conductive structures extend laterally outward from the active region.

6. The method of claim 1, further comprising:
forming a polysilicon structure above the active region such that the polysilicon structure extends in the first direction and is located between a first subset of the first plurality of conductive structures and a second subset of the first plurality of conductive structures.

7. The method of claim 6, wherein forming the forming a polysilicon structure comprises:
forming a polysilicon structure such that the polysilicon structure extends laterally outward from the active region.

8. A method, comprising:
forming a first plurality of conductive structures around a perimeter of an integrated circuit in a semiconductor device,
wherein the first plurality of conductive structures extend in a first direction in the semiconductor device and are arranged in a second direction in the semiconductor device that is approximately perpendicular to the first direction;
forming a second plurality of conductive structures around the perimeter of the integrated circuit,
forming a first interconnect structure around the perimeter of the integrated circuit,
wherein at least a first subset of the first plurality of conductive structures is within a footprint of the first interconnect structure; and
forming a second interconnect structure around the perimeter of the integrated circuit,
wherein at least a second subset of the first plurality of conductive structures is within a footprint of the second interconnect structure.

9. The method of claim 8, wherein forming the second plurality of conductive structures comprises:
forming the second plurality of conductive structures such that the second plurality of conductive structures extend in the second direction and are arranged in the first direction.

10. The method of claim 8, wherein forming the second plurality of conductive structures comprises:
forming the second plurality of conductive structures such that a first length of a first subset of the second plurality of conductive structures is greater than a second length of a second subset of the second plurality of conductive structures.

11. The method of claim 8, further comprising:
forming a plurality of polysilicon structures around the perimeter of the integrated circuit such that the plurality of polysilicon structures extend in the first direction.

12. The method of claim 11, wherein forming the plurality of polysilicon structures comprises:
forming the plurality of polysilicon structures such that the plurality of polysilicon structures are located between adjacent pairs of the first plurality of conductive structures.

13. The method of claim 11, wherein the plurality of polysilicon structures, the first plurality of conductive structures, and the second plurality of conductive structures are formed above an active region around the perimeter of the integrated circuit.

14. The method of claim 11, wherein at least one of the plurality of polysilicon structures is located between the first interconnect structure and the second interconnect structure.

15. The method of claim 11, wherein at least one of the plurality of polysilicon structures is located under and extends between the first interconnect structure and the second interconnect structure.

16. A method, comprising:
providing an active region around an integrated circuit of a semiconductor device;
forming, above the active region, a first plurality of conductive structures extending in a first direction of the semiconductor device and arranged in a second direction in the semiconductor device that is approximately perpendicular with the first direction; and
forming, above the active region, a second plurality of conductive structures extending in the second direction and arranged in the first direction such that the second plurality of conductive structures intersect the first plurality of conductive structures.

17. The method of claim 16, wherein the active region is a first active region of the semiconductor device; and
wherein the method further comprises:
providing a second active region around the first active region;
forming, above the second active region, a third plurality of conductive structures extending in the first direction and arranged in the second direction; and
forming, above the second active region, a fourth plurality of conductive structures extending in the second direction and arranged in the first direction such that the fourth plurality of conductive structures intersect the third plurality of conductive structures.

18. The method of claim 17, further comprising:
forming a first a plurality of polysilicon structures above the first active region,
wherein the first plurality of polysilicon structures extend in the first direction; and
forming a second plurality of polysilicon structures above the second active region,
wherein the second plurality of polysilicon structures extend in the first direction.

19. The method of claim 16, wherein the integrated circuit is a first integrated circuit of the semiconductor device;
wherein the active region is a first active region of the semiconductor device; and
wherein the method further comprises:
providing a second active region around a second integrated circuit that is adjacent to the first integrated circuit;
forming, above the second active region, a third plurality of conductive structures extending in the first direction and arranged in the second direction; and
forming, above the second active region, a fourth plurality of conductive structures extending in the second direction and arranged in the first direction such that the fourth plurality of conductive structures intersect the third plurality of conductive structures.

20. The method of claim 19, further comprising:
forming a first a plurality of polysilicon structures above the first active region,
wherein the first plurality of polysilicon structures extend in the first direction; and
forming a second plurality of polysilicon structures above the second active region,
wherein the second plurality of polysilicon structures extend in the first direction.
